(19) United States
(12) Patent Application Publication
(10) Pub. No.: US 2025/0337436 A1
(43) Pub. Date: Oct. 30, 2025

(54) ENCODING METHOD, DECODING METHOD, ENCODER, DECODER, AND STORAGE MEDIUM

(71) Applicant: GUANGDONG OPPO MOBILE TELECOMMUNICATIONS CORP., LTD., Dongguan (CN)

(72) Inventors: Fuzheng YANG, Dongguan (CN); Junyan HUO, Dongguan (CN); Yanzhuo MA, Dongguan (CN); Ming LI, Dongguan (CN)

(73) Assignee: GUANGDONG OPPO MOBILE TELECOMMUNICATIONS CORP., LTD., Dongguan (CN)

(21) Appl. No.: 19/262,676

(22) Filed: Jul. 8, 2025

Related U.S. Application Data
(63) Continuation of application No. PCT/CN2023/071452, filed on Jan. 9, 2023.

(51) Int. Cl. H03M 7/30

(52) U.S. Cl. CPC H03M 7/70

(57) ABSTRACT

Embodiments of this application disclose an encoding method, a decoding method, a code stream, an encoder, a decoder, and a storage medium. The decoding method comprises: determining occupancy information of reference child nodes of a current child node; determining preset identification information of the current child node on the basis of the occupancy information of the reference child nodes; determining context information of the current child node on the basis of the preset identification information; and decoding, on the basis of the context information, a syntactic element to be decoded of the current child node, and determining the value of said syntactic element.

### CROSS-REFERENCE TO RELATED APPLICATIONS

This application is a continuation of International Application No. PCT/CN2023/071452, filed on Jan. 9, 2023, the disclosure of which is hereby incorporated by reference in its entirety.

### TECHNICAL FIELD

Embodiments of this application relate to the field of point cloud coding technologies, and in particular, to an encoding/decoding method, a bitstream, an encoder, a decoder, and a storage medium.

### BACKGROUND

Currently, in a coding framework of geometry-based point cloud compression (Geometry-based Point Cloud Compression, G-PCC), geometric information of a point cloud and attribute information corresponding to a point in the point cloud are separately encoded. In the G-PCC coding framework, geometry coding mainly includes octree-based geometry coding, Trisoup-based geometry coding, and prediction tree-based geometry coding.

In a related technology, a purpose of constructing context information is to perform conditional encoding by using an encoded syntax element, thereby improving encoding performance. However, some information in the context information lacks an actual meaning or is invalid, which reduces encoding performance in use of context.

### SUMMARY

Embodiments of this application provide an encoding method, a decoding method, a code stream, an encoder, a decoder, and a storage medium, which can improve accuracy of constructed context information, and further improve encoding and decoding efficiency.

Technical solutions in embodiments of this application may be implemented as follows.

According to a first aspect, an embodiment of this application provides a decoding method, applied to a decoder, and method includes:
determining occupancy information of reference child nodes of a current child node;
determining preset identifier information of the current child node based on the occupancy information of the reference child nodes;
determining context information of the current child node based on the preset identifier information; and
decoding a to-be-decoded syntax element of the current child node based on the context information, to determine a value of the to-be-decoded syntax element.

According to a second aspect, an embodiment of this application provides an encoding method, applied to an encoder, and the method includes:
determining occupancy information of reference child nodes of a current child node;
determining preset identifier information of the current child node based on the occupancy information of the reference child nodes;
determining context information of the current child node based on the preset identifier information; and
encoding a value of a to-be-encoded syntax element of the current child node based on the context information, and writing an encoded bit into a bitstream.

According to a third aspect, an embodiment of this application provides a bitstream, and the bitstream is generated by performing bit encoding on to-be-encoded information. The to-be-encoded information includes at least one of the following: a value of to-be-encoded syntax element of a current child node.

According to a fourth aspect, an embodiment of this application provides an encoder, and the encoder includes a first determining unit and an encoding unit.

The first determining unit is configured to: determine occupancy information of reference child nodes of a current child node; determine preset identifier information of the current child node based on the occupancy information of the reference child nodes; and determine context information of the current child node based on the preset identifier information;

The encoding unit is configured to: encode a value of a to-be-encoded syntax element of the current child node based on the context information, and write an encoded bit into a bitstream.

According to a fifth aspect, an embodiment of this application provides an encoder, including a first memory and a first processor.

The first memory is configured to store a computer program runnable on the first processor.

The first processor is configured to run the computer program to execute the method according to the second aspect.

According to a sixth aspect, an embodiment of this application provides a decoder, and the decoder includes a second determining unit and a decoding unit.

The second determining unit is configured to: determine occupancy information of reference child nodes of a current child node; determine preset identifier information of the current child node based on the occupancy information of the reference child nodes; and determine context information of the current child node based on the preset identifier information.

The decoding unit is configured to decode a to-be-decoded syntax element of the current child node based on the context information, to determine a value of the to-be-decoded syntax element.

According to a seventh aspect, an embodiment of this application provides a decoder, including a second memory and a second processor.

The second memory is configured to store a computer program runnable on the second processor.

The second processor is configured to run the computer program to execute the method according to the first aspect.

According to an eighth aspect, an embodiment of this application provides a computer-readable storage medium, where the computer-readable storage medium stores a computer program, and the computer program is executed to implement the method according to the first aspect or the method according to the second aspect.

Embodiments of this application provide a decoding method, a bitstream, an encoder, a decoder, and a storage medium. On both an encoding side and a decoding side, occupancy information of reference child nodes of a current child node is first determined; preset identifier information of the current child node is determined based on the occupancy information of the reference child nodes; and context information of the current child node is determined based on the preset identifier information. Finally, on the encoding side, a value of a to-be-encoded syntax element of the current child node is encoded based on the context information, and an encoded bit is written into a bitstream, so that on the decoding side, the to-be-decoded syntax element of the current child node is decoded based on the context information, and the value of the to-be-decoded syntax element can be determined.

### BRIEF DESCRIPTION OF DRAWINGS

FIG. 1 is a schematic diagram of a network architecture of point cloud coding.

FIG. 2 is a schematic diagram of a framework of a G-PCC encoder.

FIG. 3 is a schematic diagram of a framework of a G-PCC decoder.

FIG. 4 is a schematic diagram of a framework of a CABAC arithmetic encoder.

FIG. 5 is a schematic diagram of a procedure for dynamically adjusting context.

FIG. 6 is a schematic diagram of a priority for dynamically adjusting context.

FIG. 7 is a schematic diagram of a scanning order of child nodes in a current node.

FIG. 8 is a schematic diagram of distribution of child neighbor nodes and coplanar parent neighbor nodes of a child node 0.

FIG. 9 is a schematic diagram of a distribution sequence of 20 parent neighbor nodes of a child node 0.

FIG. 10 is a schematic flowchart of a decoding method according to an embodiment of this application.

FIG. 11 is a schematic flowchart of an encoding method according to an embodiment of this application.

FIG. 12 is a schematic diagram of a procedure for dynamic reduction of context information according to an embodiment of this application.

FIG. 13 is a schematic diagram of a procedure for updating dynamic reduction of context information according to an embodiment of this application.

FIG. 14 is a schematic diagram of a structure of an encoder according to an embodiment of this application.

FIG. 15 is a schematic diagram of a hardware structure of an encoder according to an embodiment of this application.

FIG. 16 is a schematic diagram of a structure of a decoder according to an embodiment of this application.

FIG. 17 is a schematic diagram of a hardware structure of a decoder according to an embodiment of this application.

FIG. 18 is a schematic structural diagram of a coding system according to an embodiment of this application.

### DESCRIPTION OF EMBODIMENTS

To understand features and technical contents of embodiments of this application in more detail, the following describes implementation of embodiments of this application in detail with reference to the accompanying drawings. The accompanying drawings are merely used for description, and are not intended to limit embodiments of this application.

Unless otherwise defined, all technical and scientific terms used in this specification have the same meaning as commonly understood by those skilled in the technical field of this application. The terms used herein are merely for the purpose of describing embodiments of this application, but are not intended to limit this application.

In the following description, the term “some embodiments” describes a subset of all possible embodiments, but it may be understood that “some embodiments” may be the same subset or different subsets of all possible embodiments and may be combined without a conflict. It should also be noted that the term “first/second/third” used in embodiments of this application is merely used to distinguish between similar objects and does not represent a specific order of objects. It may be understood that “first/second/third” may be interchanged if allowed, so that the embodiments of this application described herein may be implemented in a sequence other than the sequence illustrated or described herein.

The names and terms used in embodiments of this application are described before providing a more detailed description of embodiments of this application, and the names and terms used in embodiments of this application are applicable to the following explanations:
point cloud compression (Point Cloud Compression, PCC);
geometry-based point cloud compression (Geometry-based Point Cloud Compression, G-PCC or GPCC);
video-based point cloud compression (Video-based Point Cloud Compression, V-PCC or VPCC);
octree (Octree);
triangle soup (Triangle soup, Trisoup);
K nearest neighbor (K Nearest Neighbor, KNN);
level of detail (Level of Detail, LOD);
predicting transform (Predicting Transform);
lifting transform (Lifting Transform);
region adaptive hierarchal transform (Region Adaptive Hierarchal Transform, RAHT); and
context-based adaptive binary arithmetic coding (Context-based Adaptive Binary Arithmetic Coding, CABAC).

A point cloud is a three-dimensional representation of a surface of an object. A point cloud (data) on a surface of an object may be collected by using a collection device such as an optoelectronic radar, a laser radar, a laser scanner, and a multi-angle camera.

The point cloud is a set of massive three-dimensional points, and a point in the point cloud may include location information of the point and attribute information of the point. For example, the location information of the point may be three-dimensional coordinate information of the point, and may also be referred to as geometric information of the point. For example, the attribute information of the point may include color information, reflectivity, and/or the like. For example, the color information may be information in any color space. For example, the color information may be RGB information, where R denotes red (Red, R), G denotes green (Green, G), and B denotes blue (Blue, B). For another example, the color information may be information about luminance and chrominance (YCbCr, YUV), where Y denotes luminance, Cb(U) denotes blue chroma, and Cr(V) denotes red chroma.

For a point cloud obtained according to the laser measurement principle, a point in the point cloud may include three-dimensional coordinate information of the point and laser reflectance (reflectance) of the point. For another example, for a point cloud obtained according to the photographing measurement principle, a point in the point cloud may include three-dimensional coordinate information of the point and color information of the point. For another example, for a point cloud obtained with reference to the laser measurement principle and photographing measurement principle, a point in the point cloud may include three-dimensional coordinate information of the point, laser reflectance of the point, and color information of the point.

Point clouds may be classified into the following three types according to acquisition methods.

Type 1: Static point cloud, for which an object is still, and a device for acquiring the point cloud is also still.

Type 2: Dynamic point cloud, for which an object is moving, but a device for acquiring the point cloud is still.

Type 3: Dynamically acquired point cloud, for which a device for acquiring the point cloud is moving.

For example, point clouds are classified into the following two types according to their usage.

Type 1: Machine perception point cloud, which may be used in a scenario such as an autonomous navigation system, a real-time inspection system, a geographic information system, a visual sorting robot, or a disaster relief robot.

Type 2: Human eye perception point cloud, which may be used in a point cloud application scenario such as a digital cultural heritage, free view broadcasting, three-dimensional immersion communication, or three-dimensional immersion interaction.

Since a point cloud is a collection of massive points, storing the point cloud consumes a large amount of memory, and is also not conducive to transmission. In addition, there is no such bandwidth that may support direct transmission of a point cloud without compression at a network layer. Therefore, it is necessary to compress the point cloud.

As of now, a point cloud encoding framework that can compress a point cloud may be a G-PCC coding framework or a V-PCC coding framework provided by a moving picture experts group (MPEG), or an AVS-PCC coding framework provided by an audio video standard (AVS). The G-PCC coding framework may be configured to compress the static point cloud of type 1 and the dynamically acquired point cloud of type 3, and the V-PCC coding framework may be configured to compress the dynamic point cloud of type 2. The G-PCC coding framework is mainly described in embodiments of this application.

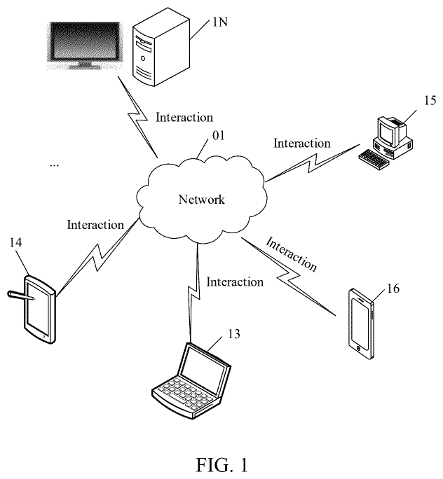

Embodiments of this application provide a network architecture of a point cloud coding system including a decoding method and an encoding method. FIG. 1 is a schematic diagram of a network architecture of point cloud coding according to an embodiment of this application. As shown in FIG. 1, the network architecture includes one or more electronic devices 13 to 1N and a communication network 01. The electronic devices 13 to 1N may perform video interaction with each other through the communication network 01. In an implementation process, the electronic devices may be various types of devices with a coding function. For example, the electronic devices may include a mobile phone, a tablet computer, a personal computer, a personal digital assistant, a navigator, a digital telephone, a video telephone, a television set, a sensing device, and a server. This is not limited in embodiments of this application. The decoder or the encoder in embodiments of this application may be the foregoing electronic device.

The electronic devices in embodiments of this application have a point cloud coding function, and generally include a point cloud encoder (namely, an encoder) and a point cloud decoder (namely, a decoder).

The following describes related technologies by using the G-PCC coding framework as an example.

It may be understood that, in a point cloud G-PCC coding framework, point cloud data to be encoded is first partitioned into a plurality of slices through slicing. In each slice, geometric information and attribute information of the point cloud are separately encoded.

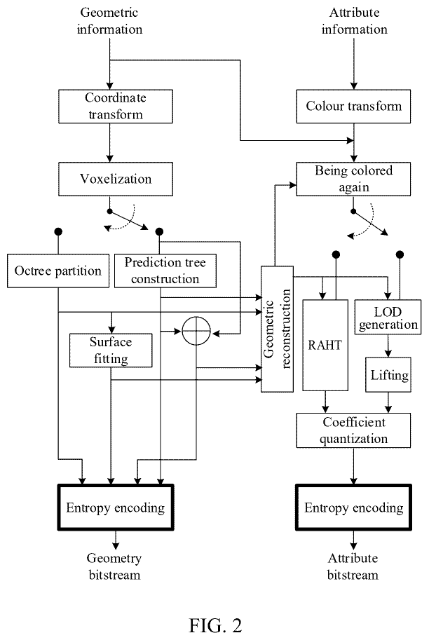

FIG. 2 is a schematic diagram of a framework of a G-PCC encoder. As shown in FIG. 2, in a geometric encoding process, coordinate transform is performed on geometric information, so that the whole point cloud is included in a bounding box, and then quantization is performed. The quantization in this step mainly plays a role of scaling. Because of rounding operations in the quantization, a part of the point cloud has the same geometric information. Then whether to remove duplicate points is determined based on a parameter. The process of quantization and removal of duplicate points is also referred to as voxelization. Next, octree partition or prediction tree construction is performed on the bounding box. In this process, entropy encoding is performed on points in leaf nodes obtained by partition, to generate a binary geometry bitstream; or entropy encoding (surface fitting based on vertices) is performed on vertices generated by partition to generate a binary geometry bitstream. In an attribute encoding process, geometric encoding is already completed. After the geometric information is reconstructed, color transform is required to be performed first, and color information (namely, attribute information) is transformed from RGB color space to YUV color space. Then, the point cloud is colored again by using the reconstructed geometric information, so that attribute information that is not encoded corresponds to the reconstructed geometric information. The attribute encoding is mainly performed on color information. In a process of encoding the color information, there are mainly two transform methods: one is distance-based lifting transformation depending on LOD partition, and the other is RAHT transformation. Both methods make the color information be transformed from a spatial domain to a frequency domain, obtaining a high-frequency coefficient and a low-frequency coefficient. Finally, the coefficients are quantized to obtain quantized coefficients, and then entropy encoding is performed on the quantized coefficients to generate a binary attribute bitstream.

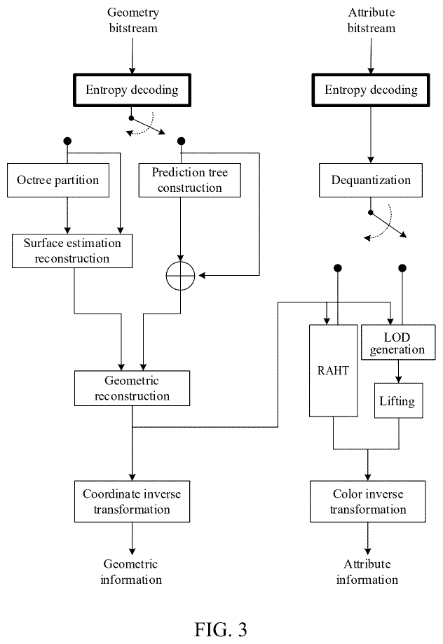

FIG. 3 is a schematic diagram of a framework of a G-PCC decoder. As shown in FIG. 3, for an acquired binary bitstream, a geometric bitstream and an attribute bitstream in the binary bitstream are first separately decoded. To decode the geometry bitstream, entropy decoding is first performed, then one of the following manners is selected: octree partition-surface reconstruction estimation or prediction tree construction, followed by geometric reconstruction-coordinate inverse transformation, and geometric information of a point cloud may be obtained. To decode the attribute bitstream, entropy decoding and dequantization are first performed, then one of the following manners is selected: RAHT transformation or LOD partition-lifting transform, finally color inverse transformation is performed, and the attribute information of the point cloud may be obtained. Data of the point cloud to be encoded can be restored based on the geometric information and the attribute information.

It should be noted that, as shown in FIG. 2 or FIG. 3, currently G-PCC geometry coding may be octree-based geometry coding, Trisoup-based geometry coding, or prediction tree-based geometry coding. Details are as follows.

### (a) Octree-Based Geometry Coding

On an encoding side, coordinate transform is first performed on geometric information, so that the whole point cloud is included in a bounding box (Bounding Box) determined by two extreme points (0, 0, 0) and (2d, 2d, 2d), and then voxelization, namely, quantization, rounding operation, or removal of duplicate points (determined depending on a parameter) is performed. Next, octree partition is continuously performed on sub-cubes that are not empty (including points in the point cloud) in the bounding box in a breadth-first traversal sequence. In a same octree depth, one node is partitioned into eight child nodes and partition is continue to be performed until a leaf node obtained becomes a unit cube of 1×1×1. 8 bits (Bits) binary code generated for determining whether occupancy occurs in a sub-cube (being occupied is represented by 1 and being unoccupied is represented by 0) is called occupancy code. Occupancy code of respective nodes is encoded to generate a binary code stream.

On a decoding side, parsing is continuously performed in a breadth-first traversal sequence to obtain occupancy code of respective nodes, and the respective nodes are sequentially partitioned continuously until a unit cube of 1×1×1 is obtained. Then parsing is performed to obtain a quantity of points included in each leaf node, and finally geometric reconstruction point cloud information is obtained.

### (b) Trisoup-Based Geometry Coding

On the encoding side, octree is first partitioned. Different from the octree-based geometry coding, this method does not require partitioning the point cloud into bottom-level leaf nodes with a side length of 1×1×1 step by step, but requires partitioning the point cloud into leaf nodes with a specified side length. Then, surface information formed by voxels in the nodes is represented by a series of triangle meshes. In GPCC, a parameter Trisoup node size may be used to represent a size of a block in which a triangular mesh is located. When the Trisoup node size is greater than 0, a voxel set in a node is represented by using a geometric mesh, and at most twelve vertices generated by a geometric mesh and twelve edges of the block are referred to as vertices. Vertex coordinates of respective blocks are sequentially encoded to generate a binary bitstream.

On the decoding side, to decode geometric coordinates of the point cloud from the triangular mesh of the node, it is necessary to check whether each voxel in the node cube intersects with the triangular mesh. This technique is called triangular rasterization, that is, intersection tests are performed using six unit vectors (0, 0, 1), (0, 0, 1), (0, 0, 1), (0, 0, 1), (0, 0, 1), and (0, 0, 1), to determine whether respective unit vectors intersect with the triangular mesh. If an intersection occurs, an intersection point is calculated and a decoded cube is output. A quantity of points generated in the decoder is determined by a mesh distance d.

### (c) Prediction Tree-Based Geometry Coding

On an encoding side, sorting is performed on an input point cloud. Sorting methods currently used include disordering, Morton ordering, azimuth ordering, and radial distance ordering. On the encoding side, a prediction tree structure is established in two different modes: high-latency slow mode (KD-Tree, KD tree) and low-latency fast mode (assigning the points to different lasers by using LiDAR calibration information, and building a predictive tree structure based on different lasers). Next, based on the prediction tree structure, each node in the prediction tree is traversed, geometric location information of the node is predicted by selecting different prediction modes to obtain a prediction residual, and the prediction residual is quantized by using a quantization parameter. Finally, encoding is performed on the prediction residual of location information of the prediction tree node, the prediction tree structure, the quantization parameter, and the like by means of continuous iteration, to generate a binary bitstream.

A prediction tree structure is reconstructed on the decoding side by continuously parsing bitstreams, then prediction residual information of geometric locations of respective prediction nodes and quantization parameters are obtained through parsing, and dequantization is performed on the prediction residual to obtain reconstructed geometric location information of respective nodes. Finally, geometric reconstruction on the decoding end is completed.

It should be further noted that, in a possible implementation of a related technology, an encoder currently used in G-PCC is a context-based adaptive binary arithmetic coding CABAC. This is a form of entropy encoding widely used in video coding. Similar to conventional arithmetic coding, the CABAC uses a recursive interval partitioning method for coding representation. Because the CABAC is adaptive coding, a probability model is adjusted with occurrence of symbols, so that a statistical characteristic of an information source is fully considered, and coding efficiency is greatly improved. The CABAC encoder may include three parts: binarization, context modeling, and binary arithmetic coding. Details are as follows.

(1) Binarization: Binarization is a process of mapping a given non-binary syntax element into a binary sequence, namely, a bin string. If the input syntax element is a binary syntax element, binary processing is omitted, and data is directly transmitted to a next step through a bypass.

(2) Context modeling: The encoder assigns a proper probability model to each input bin based on a value of previously encoded syntax element or bin. This process is the context modeling.

(3) Binary arithmetic coding: There are two coding modes available for selection: regular coding mode and bypass coding mode. In the regular coding mode, the bin of the syntax element is transmitted together with the probability model assigned to the bin to the binary arithmetic encoder for coding and the context model is updated based on the value of the bin. This is the adaptive process in coding. Another mode is the bypass coding mode, which does not need to assign a specific probability model for each bin. An input bin is encoded directly by using a simple bypass encoder, which can speed up the entire encoding and decoding process.

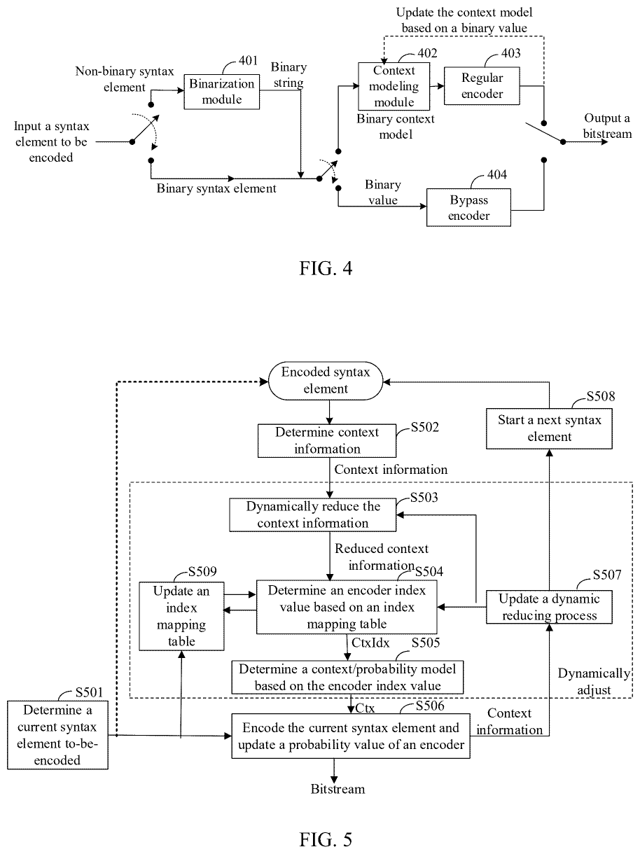

For example, FIG. 4 is a schematic diagram of a framework of a CABAC arithmetic encoder. As shown in FIG. 4, an overall structure of the CABAC arithmetic encoder may include a binarization module 401, a context modeling module 402, a regular encoder 403, and a bypass encoder 404. After a to-be-encoded syntax element is input, it is first determined whether the to-be-encoded syntax element is a binary syntax element. If the to-be-encoded syntax element is a non-binary syntax element, the to-be-encoded syntax element may be converted into a binary string by the binarization module 401; otherwise, if the to-be-encoded syntax element is a binary syntax element, a probability model is directly assigned in a next part. In this case, there may be two options. One is to encode through the context modeling module 402 and the regular encoder 403, and in this case, the context model needs to be updated based on a binary value; and the other is to encode the binary value directly by using the bypass encoder 404, and finally a bitstream is output.

It should be further noted that, in another possible implementation of the related technology, a context may be dynamically adjusted in the following manner: (1) context information of occupancy code to be encoded is acquired and reduced, and information required to be reduced is dynamically adjusted with an encoding process; and (2) the reduced context information is mapped to a set of a relatively small quantity of binary encoders, and each time after encoding of occupancy code is completed, the index mapping relationship is also updated.

For example, FIG. 5 is a schematic diagram of a procedure for dynamically adjusting context. As shown in FIG. 5, the procedure may include the following steps:
S501. determining a to-be-encoded current syntax element;
S502. determining context information;
S503. dynamically reducing the context information to determine a dynamically reduced context state;
S504. determining an encoder index value based on an index mapping table;
S505. determining a context/probability model based on the encoder index value;
S506: encoding the current syntax element and updating a probability value of an encoder;
S507. updating a dynamic reducing process;
S508. starting a process for a next syntax element; and
S509. updating an index mapping table.

It should be understood that, in embodiments of this application, the index mapping table may refer to an encoder mapping table (Look Up Table, LUT)/context index table, and provides a mapping relationship between a context state and an encoder index value. Based on the mapping table, an encoder index value (CtxIdx) that should be used by a to-be-encoded syntax element in any context state may be obtained; then a corresponding context/probability model may be determined based on a context/probability model table, that is, a corresponding target encoder (Ctx) is determined, and finally encoding processing is performed on the current syntax element by using the target encoder. In addition, each time when one syntax element is encoded, the mapping relationship between a context state and an encoder index value in the mapping table is adjusted based on a result of the syntax element.

It should be further understood that, in embodiments of this application, for an implementation of dynamically adjusting the context, context information may be formed by an encoded syntax element, and may be classified into primary information and secondary information depending on importance of the information. Some information in the secondary information is reduced in the dynamic reducing process, and a context obtained by combining the primary information and the reduced secondary information is used as inputs of the method and mapped to the encoder for encoding.

Further, for a context information construction process, context information of a to-be-encoded child node may be determined based on the following types of information:
i local sparsity of the to-be-encoded child node;
ii location information of the to-be-encoded child node and an occupancy status of an encoded sibling node;
iii an occupancy status of six coplanar parent neighbors of a current node;
iv an occupancy status of other 20 co-edge or co-point parent neighbors of the current node.

Herein, the context information is converted into a binary stream (bins), where information more relevant to the current child node is located in a higher bit of the bins as primary information, and information less relevant to the current child node is located in a lower bit of the bins as secondary information.

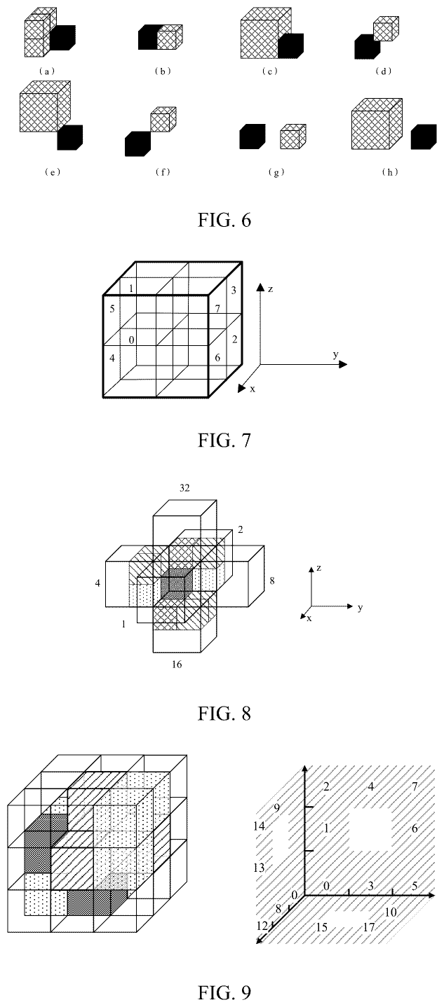

It should be noted that, the context information may be ranked in an order of importance as follows: an encoded sibling node of the current child node>an encoded coplanar child node neighbor of the current child node>an encoded co-edge child node neighbor of the current child node>an encoded co-point child node neighbor of the current child node>another encoded child node neighbor of the current child node>an encoded coplanar parent node neighbor of the current child node>an encoded co-edge parent node neighbor of the current child node>20 other encoded parent node neighbors. For example, FIG. 6 is a schematic diagram of a priority for dynamically adjusting context. As shown in FIG. 6, a black-filled child node is a current child node, and eight cases are provided herein. In part (a), a grid-filled child node is a sibling child node of the current child node; in part (b), a grid-filled child node is a coplanar neighbor child node of the current child node; in part (c), a grid-filled child node is a coplanar neighbor parent node of the current child node; in part (b), a grid-filled child node is a co-edge neighbor child node of the current child node; in part (e), a grid-filled child node is an adjacent neighbor parent node of the current child node; in part (f), a grid-filled child node is a co-point neighbor child node of the current child node; in part (g), a grid-filled child node is a non-adjacent neighbor child node of the current child node; in part (h), a grid-filled child node is a non-adjacent neighbor parent node of the current child node.

It should be further noted that, during construction of context information, different context models may be first constructed for to-be-encoded child nodes, located at different locations, of the current node according to a preset scanning order. For example, FIG. 7 is a schematic diagram of a scanning order of child nodes in a current node. The scanning order is an order of child node 0, child node 1, child node 2, child node 3, child node 4, child node 5, child node 6, and child node 7 in FIG. 7, which is used to sequentially construct different context models. In addition, as a quantity of encoded child nodes in the current node increases, valid context information that may be referenced by a non-encoded child node also changes. Moreover, there are different modes for determining local sparsity of the eight child nodes of the current node, so that each child node has its own context bin.

(1) The child node 0 has a coplanar child node neighbor, a co-edge child node neighbor, and a co-point child node neighbor, and has no encoded sibling node. The child node 0 also has a coplanar parent node neighbor and 20 other encoded neighbors that can be referenced. When it is determined to be non-sparse, the context bins include 19 bits, with a maximum of 2¹⁹ states. The most significant 6 bits are used as primary information and the least significant 13 bits as non-reduced secondary information. When it is determined to be sparse, the context bins include 16 bits, with a maximum of 2¹⁶ states. The most significant 4 bits are used as primary information and the least significant 12 bits as non-reduced secondary information.

Local sparsity of the child node 0 may be determined based on a number of occupied child nodes (NN) of twelve encoded child nodes adjacent to the current child node in the negative directions of x, y, and z axes in FIG. 8, where the number of occupied child nodes NN>1 indicates being non-sparse, and the number of occupied child nodes NN≤1 indicates being sparse. For example, FIG. 8 is a schematic diagram showing distribution of child neighbor nodes and coplanar parent neighbor nodes of the child node 0, and FIG. 9 is a schematic diagram showing a distribution sequence of 20 parent neighbor nodes of the child node 0. Numbers such as 1, 2, 4, 8, 16, and 32 indicate serial numbers of the neighbor nodes.

Herein Table 1 shows interpretation of context information of each bit corresponding to the child node 0, and an order from the most significant bit to the least significant bit reflects important of information. Flag bits of a current category are represented by 1 or 0 in black cells, and the negation operation “!” indicates that information of a symbol of a bit is negation of an actual symbol of the bit. In addition, Table 1 also includes coplanar child nodes, co-edge child nodes, co-point child nodes, between-edge child nodes, co-bit child nodes, and the like. In Table 1, meanings of symbols are respectively explained as follows: B (Bottom), F (Front), and L (left) are six-neighbor parent neighbors numbered 16, 4, and 2, respectively, which are coplanar with a current node in FIG. 8. Because the three encoded nodes are located in negative directions of coordinate axes of the current node, occupancy information of child nodes of the three encoded nodes may be obtained. Therefore, Table 1 lists each of coplanar child nodes, co-edge child nodes, and co-point child nodes of the current child node in the three directions. It should be noted that, for example, English abbreviations B, F, and L respectively indicate coplanar child nodes, co-edge child nodes, and co-point child nodes of the current child node, for example, English full names Bottom, Front, and Left respectively indicate co-planar parent neighbors, co-edge parent neighbors, and co-point parent neighbors of the current child node. Top, Back, and Right are six-neighbor parent neighbors numbered 32, 8, and 1, respectively, which are coplanar with the current node in FIG. 8. Because the three encoded nodes are located in positive directions of the coordinate axes of the current node, occupancy information of child nodes of the three encoded nodes cannot be obtained, and correlation of the three encoded nodes is weaker than that of the foregoing 12 neighbor nodes. Other numbers such as 9, 4, 1, and 2 in Table 1 are sequence numbers of 20 co-edge/co-point neighbors of the current node except the six-coplanar parent neighbors shown in FIG. 9. The co-bit child nodes _{bit0}B, _{bit0}F, and _{bit0}L in Table 1 are understood as child nodes whose number is 0 in the encoded Bottom, Front, and Left nodes, which are thus referred to as co-bit child nodes. In Table 1, LF, LB, and FB represented by two letters respectively denote occupancy information (obtained through occupancy code of a neighbor numbered 1 in the 20 neighbors) of two child nodes sharing an edge with the current child node and located between the Left and Front directions, occupancy information (obtained through occupancy code of a neighbor numbered 8 in the 20 neighbors) of two child nodes sharing an edge with the current child node and located between the Left and Bottom directions, and occupancy information (obtained through occupancy code of a neighbor numbered 3 in the 20 neighbors) of two child nodes sharing an edge with the current child node and located between the Front and Bottom directions.

(2) The child node 1 has a coplanar child node neighbor, a co-edge child node neighbor, and a co-point child node neighbor, has one encoded sibling node bit0, and has a coplanar parent node neighbor and 20 other encoded neighbors that can be referenced. When it is determined to be non-sparse, the context bins include 19 bits, with a maximum of 2¹⁹ states. The most significant 6 bits are used as primary information and the least significant 13 bits as non-reduced secondary information. When it is determined to be sparse, the context bins include 19 bits, with a maximum of 2¹⁹ states. The most significant 7 bits are used as primary information and the least significant 12 bits as non-reduced secondary information.

Local sparsity of the child node 1 may be determined based on a number of occupied child nodes (NN) of four encoded child nodes adjacent to the current child node in the negative direction (Front) of y-axis in FIG. 8, where the number of occupied child nodes NN>0 indicates being non-sparse, and the number of occupied child nodes NN=0 indicates being sparse. Herein, Table 2 shows interpretation of context information of each bit in the bins, and it can be learned that an encoded sibling node 0 occupies most important information and is located at a most significant bit of the bins.

(3) The child node 2 has a coplanar child node neighbor, a co-edge child node neighbor, and a co-point child node neighbor, has two encoded sibling nodes bit0 and bit1, and has a coplanar parent node neighbor and 20 other encoded neighbors that can be referenced. When it is determined to be non-sparse, the context bins include 19 bits, with a maximum of 2¹⁹ states. The most significant 6 bits are used as primary information and the least significant 13 bits as non-reduced secondary information. When it is determined to be sparse, the context bins include 19 bits, with a maximum of 2¹⁹ states. The most significant 7 bits are used as primary information and the least significant 12 bits as non-reduced secondary information.

Local sparsity of the child node 2 may be determined based on a number of occupied child nodes (NN) of four encoded child nodes adjacent to the current child node in the negative direction (Bottom) of z-axis in FIG. 8, where the number of occupied child nodes NN>0 indicates being non-sparse, and the number of occupied child nodes NN=0 indicates being sparse. Herein, Table 3 shows interpretation of context information of each bit in the bins, and it can be learned that an encoded sibling node 0 occupies most important information and is located at a most significant bit of the bins.

(4) The child node 3 has a coplanar child node neighbor, a co-edge child node neighbor, and a co-point child node neighbor, has three encoded sibling nodes bit0, bit1 and bit2, and has a coplanar parent node neighbor and 20 other encoded neighbors that can be referenced. When it is determined to be non-sparse, the context bins include 17 bits, with a maximum of 2¹⁷ states. The most significant 6 bits are used as primary information and the least significant 11 bits as non-reduced secondary information. When it is determined to be sparse, the context bins include 18 bits, with a maximum of 2¹⁸ states. The most significant 6 bits are used as primary information and the least significant 12 bits as non-reduced secondary information.

Local sparsity of the child node 3 may be determined based on an NN of seven nodes including three nodes bit0+bit1+bit2 and four encoded nodes adjacent to the current child node in the negative direction of x-axis in FIG. 8, where the number of occupied child nodes NN>1 indicates being non-sparse, and the number of occupied child nodes NN≤1 indicates being sparse.

(5) The child node 4 has a coplanar child node neighbor, a co-edge child node neighbor, and a co-point child node neighbor, has four encoded sibling nodes bit0, bit1, bit2 and bit3, and has a coplanar parent node neighbor and 20 other encoded neighbors that can be referenced. When it is determined to be non-sparse, the context bins include 19 bits, with a maximum of 2¹⁹ states. The most significant 6 bits are used as primary information and the least significant 13 bits as non-reduced secondary information. When it is determined to be sparse, the context bins include 16 bits, with a maximum of 2¹⁶ states. The most significant 4 bits are used as primary information and the least significant 12 bits as non-reduced secondary information.

Local sparsity of the child node 4 may be determined based on an NN of twelve nodes including four nodes bit0+bit1+bit2+bit3 (denoted as “new Left”), four encoded nodes adjacent to the current child node in the negative direction (Front) of y axis, and four encoded nodes adjacent to the current child node in the negative direction (Bottom) of z-axis in FIG. 8, where the number of occupied child nodes NN>1 indicates being non-sparse, and the number of occupied child nodes NN≤1 indicates being sparse.

(5) The child node 5 has a coplanar child node neighbor, a co-edge child node neighbor, and a co-point child node neighbor, has five encoded sibling nodes bit0, bit1, bit2, bit3, and bit4, and has a coplanar parent node neighbor and 20 other encoded neighbors that can be referenced. When it is determined to be non-sparse, the context bins include 19 bits, with a maximum of 2¹⁹ states. The most significant 6 bits are used as primary information and the least significant 13 bits as non-reduced secondary information. When it is determined to be sparse, the context bins include 19 bits, with a maximum of 2¹⁹ states. The most significant 7 bits are used as primary information and the least significant 12 bits as non-reduced secondary information.

Local sparsity of the child node 5 may be determined based on an NN of child nodes adjacent to the current child node in the negative direction (Front) of y-axis in FIG. 8, where the number of occupied child nodes NN>0 indicates being non-sparse, and the number of occupied child nodes NN=0 indicates being sparse.

(7) The child node 6 has a coplanar child node neighbor, a co-edge child node neighbor, and a co-point child node neighbor, has six encoded sibling nodes bit0, bit1, bit2, bit3, bit4, and bit5, and has a coplanar parent node neighbor and 20 other encoded neighbors that can be referenced. When it is determined to be non-sparse, the context bins include 19 bits, with a maximum of 2¹⁹ states. The most significant 6 bits are used as primary information and the least significant 13 bits as non-reduced secondary information. When it is determined to be sparse, the context bins include 19 bits, with a maximum of 2¹⁹ states. The most significant 7 bits are used as primary information and the least significant 12 bits as non-reduced secondary information.

Local sparsity of the child node 6 may be determined based on an NN of child nodes adjacent to the current child node in the negative direction (Bottom) of z-axis in FIG. 8, where the number of occupied child nodes NN>0 indicates being non-sparse, and the number of occupied child nodes NN=0 indicates being sparse.

(8) The child node 7 has no coplanar child node neighbor, co-edge child node neighbor, or co-point child node neighbor, has seventh encoded sibling nodes bit0, bit0, bit1, bit2, bit3, bit4, bit5, and bit6, and has a coplanar parent node neighbor and 20 other encoded neighbors that can be referenced. When it is determined to be non-sparse, the context bins include 17 bits, with a maximum of 2¹⁷ states. The most significant 6 bits are used as primary information and the least significant 11 bits as non-reduced secondary information. When it is determined to be sparse, the context bins include 18 bits, with a maximum of 2¹⁸ states. The most significant 6 bits are used as primary information and the least significant 12 bits as non-reduced secondary information.

Local sparsity of the child node 7 may be determined based on an NN of seven nodes including bit0+bit1+bit2+bit3+bit4+bit5+bit6, where the number of occupied child nodes NN>1 indicates being non-sparse, and the number of occupied child nodes NN≤ 1 indicates being sparse.

Briefly, in a related technology, a purpose of constructing context information is to perform conditional encoding by using a syntax element that has already been encoded, thereby improving encoding performance. However, in a related technology, specific encoded symbol information and the corresponding identifier information are used as a context, but existing identifier information lacks an actual meaning and may not be referred to as a valid context, and a negation operation on some bits in context bins causes the encoded symbol bit to lose its original meaning. According to the conditional entropy theory, a more accurate condition indicates less conditional entropy, and therefore context information needs to be corrected to obtain better encoding performance.

Based on this, an embodiment of this application provides an encoding method, including: determining occupancy information of reference child nodes of a current child node; determining preset identifier information of the current child node based on the occupancy information of the reference child nodes; determining context information of the current child node based on the preset identifier information; and encoding a value of a to-be-encoded syntax element of the current child node based on the context information, and writing an encoded bit into a bitstream.

An embodiment of this application further provides a decoding method, including: determining occupancy information of reference child nodes of a current child node; determining preset identifier information of the current child node based on the occupancy information of the reference child nodes; determining context information of the current child node based on the preset identifier information; and decoding a to-be-decoded syntax element of the current child node based on the context information, to determine a value of the to-be-decoded syntax element.

In this way, on both an encoding side and a decoding side, an actual meaning can be assigned to the identifier information in the context information, and an encoded symbol bit can be made valid. Thus, accuracy of constructed context information can be improved to select an optimal target encoder for encoding. In this way, coding efficiency and coding performance can be improved.

The following describes embodiments of this application in detail with reference to the accompanying drawings.

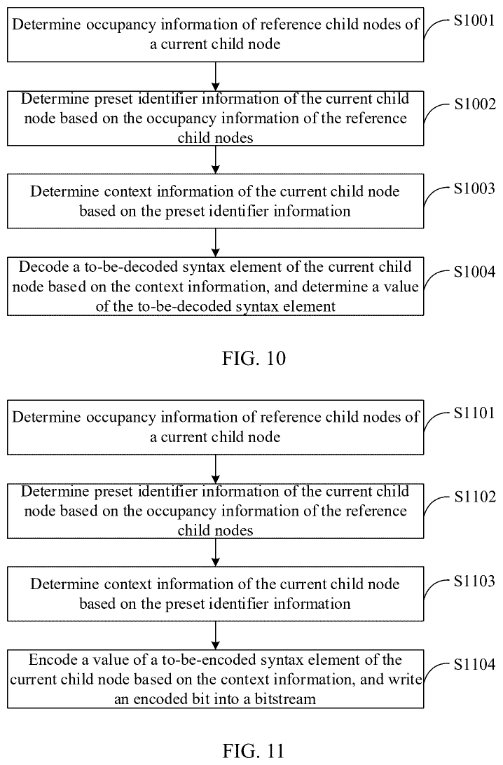

FIG. 10 is a schematic flowchart of a decoding method according to an embodiment of this application. As shown in FIG. 10, the method may include S1001 to S1004.
S1001: Occupancy information of reference child nodes of a current child node is determined.

It should be noted that the decoding method in embodiments of this application is applied to a decoder (or referred to as “entropy decoder”). In addition, the decoding method may specifically refer to a point cloud decoding method, or a point cloud entropy decoding method. More specifically, an embodiment of this application provides a context adjustment method, to make identifier information in context information have actual meaning, and may further make a decoded symbol bit be valid.

It should be further noted that, in an example of a G-PCC decoder shown in FIG. 3, the method in embodiments of this application is used to construct context information of the current child node, which is then applied to the part of entropy decoding (namely, the bold part in FIG. 3). Therefore, by improving the accuracy of the constructed context information, performance of decoding a point cloud can be improved.

It should be further noted that, in a point cloud, points may refer to all points in the point cloud, or may refer to some points in the point cloud relatively centralized in space. A current node may refer to a node currently to be decoded in the point cloud. The current node may include eight child nodes, and then to-be-decoded child nodes located at different locations of the current node are sequentially used as a current child node according to a preset scanning order (as shown in FIG. 7), so as to construct context information for the current child node, and decode a to-be-decoded syntax element of the current child node.

It should be understood that, in embodiments of this application, a reference child node refers to a co-planar neighbor node, a co-edge neighbor node, or a co-point neighbor node that is adjacent to the current child node. In some embodiments, the reference child nodes may include at least one of the following:
a decoded sibling node of the current child node;
a decoded child node adjacent to the current child node in a first preset direction;
a decoded child node adjacent to the current child node in a second preset direction;
a decoded child node adjacent to the current child node in a third preset direction; or
a decoded child node adjacent to the current child node in a fourth preset direction.

It should be noted that, in embodiments of this application, the first preset direction may refer to a negative direction (Left direction) of the x-axis of the current child node, the second preset direction may refer to a negative direction (Front direction) of a y-axis of the current child node, and the third preset direction may refer to a negative direction (Bottom direction) of a z-axis of the current child node. In addition, it should be noted that the fourth preset direction exists only when the current child node is the child node 4, the child node 5, the child node 6, or the child node 7. In this case, the fourth preset direction may refer to a new left direction formed by the child node 0, the child node 1, the child node 2, and the child node 3.

It should be further noted that, in embodiments of this application, the child node 0 may be represented by bit0, the child node 1 may be represented by bit1, the child node 2 may be represented by bit2, the child node 3 may be represented by bit3, the child node 4 may be represented by bit4, the child node 5 may be represented by bit5, the child node 6 may be represented by bit6, and the child node 7 may be represented by bit7.

Regarding the decoded sibling node of the current child node, if the current child node is the child node 0, no decoded sibling node exists; if the current child node is the child node 1, the decoded sibling node is bit0; if the current child node is the child node 2, the decoded sibling nodes are bit0 and bit1; if the current child node is the child node 3, the decoded sibling nodes are bit0, bit1, and bit2; if the current child node is the child node 4, the decoded sibling nodes are bit0, bit1, bit2, and bit3. By analogy, if the current child node is the child node 7, the decoded sibling nodes are bit0, bit1, bit2, bit3, bit4, bit5, and bit6.

For example, if the current child node is the child node 0, the reference child nodes may include a coplanar child node neighbor, a co-edge child node neighbor, and a co-point child node neighbor, include no decoded sibling node, and include a coplanar parent node neighbor, and a decoded neighbor in 20 other neighbors that can be referenced; if the current child node is the child node 1, the reference child nodes may include a coplanar child node neighbor, a co-edge child node neighbor, and a co-point child node neighbor, include one decoded sibling node bit0, and include a coplanar parent node neighbor, and a decoded neighbor in 20 other neighbors that can be referenced; if the current child node is the child node 2, the reference child nodes may include a coplanar child node neighbor, a co-edge child node neighbor, and a co-point child node neighbor, include two decoded sibling nodes bit0 and bit1, and include a coplanar parent node neighbor, and a decoded neighbor in 20 other neighbors that can be referenced; if the current child node is the child node 3, the reference child nodes may include a coplanar child node neighbor, a co-edge child node neighbor, and a co-point child node neighbor, include three decoded sibling nodes bit0, bit1, and bit2, and include a coplanar parent node neighbor, and a decoded neighbor in 20 other neighbors that can be referenced; if the current child node is the child node 4, the reference child nodes may include a coplanar child node neighbor, a co-edge child node neighbor, and a co-point child node neighbor, include four decoded sibling nodes bit0, bit1, bit2, and bit 3, and include a coplanar parent node neighbor, and a decoded neighbor in 20 other neighbors that can be referenced; if the current child node is the child node 5, the reference child nodes may include a coplanar child node neighbor, a co-edge child node neighbor, and a co-point child node neighbor, include five decoded sibling nodes bit0, bit1, bit2, bit3, and bit4, and include a coplanar parent node neighbor, and a decoded neighbor in 20 other neighbors that can be referenced; if the current child node is the child node 6, the reference child nodes may include a coplanar child node neighbor, a co-edge child node neighbor, and a co-point child node neighbor, include six decoded sibling nodes bit0, bit0, bit1, bit2, bit3, bit4, and bit5, and include a coplanar parent node neighbor, and a decoded neighbor in 20 other neighbors that can be referenced; if the current child node is the child node 7, the reference child nodes may include seven decoded sibling nodes bit0, bit0, bit1, bit2, bit3, bit4, bit5, and bit6, and include a coplanar parent node neighbor, and a decoded neighbor in 20 other neighbors that can be referenced. Herein, the child node 7 has no coplanar child node neighbor, co-edge child node neighbor, or co-point child node neighbor.

It should be further understood that, in embodiments of this application, occupancy information of a reference child node is used to indicate whether the reference child node is occupied by a point. For example, if the occupancy information of the reference child node is 1, it may indicate that the reference child node is occupied; if the occupancy information of the reference child node is 0, it may indicate that the reference child node is not occupied by any point.

S1002: Preset identifier information of the current child node is determined based on occupancy information of the reference child nodes.

It should be noted that, in embodiments of this application, an actual meaning can be assigned to the preset identifier information in the context information of the current child node. Specifically, the value of the preset identifier information may be determined based on occupancy information of the reference child nodes. In some embodiments, the determining the preset identifier information of the current child node based on the occupancy information of the reference child nodes may include:
determining identifier information of a first target bit of the current child node based on the occupancy information of the reference child nodes when the current child node meets a first condition; or
determining identifier information of a second target bit of the current child node based on the occupancy information of the reference child nodes when the current child node meets a second condition.

In embodiments of this application, the current child node meeting the first condition may include that the current child node is either a zeroth child node or a fourth child node;

In embodiments of this application, the current child node meeting the second condition may include that the current child node is one of a first child node, a second child node, a third child node, a fifth child node, and a sixth child node.

The zeroth child node (bit0), the first child node (bit1), the second child node (bit2), the third child node (bit3), the fourth child node (bit4), the fifth child node (bit5), and the sixth child node (bit6) are sequentially child nodes to be decoded in sequence according to a preset scanning order in the current node. For example, the preset scanning order may be the scanning order shown in FIG. 7.

It should be further noted that, in embodiments of this application, a local sparse category of the current child node may be further determined based on the occupancy information of the reference child nodes. In some embodiments, the method may further include:
determining a number of occupied child nodes of the reference child nodes based on the occupancy information of the reference child nodes; and
determining a local sparse category of the current child node based on the number of occupied child nodes of the reference child nodes.

Further, in some embodiments, the determining the local sparse category of the current child node based on the number of occupied child nodes of the reference child nodes may include:
in a case that the number of occupied child nodes of the reference child nodes is greater than a first threshold, determining that the local sparse category of the current child node is a first category;
in a case that the number of occupied child nodes of the reference child nodes is less than or equal to a first threshold, determining that the local sparse category of the current child node is a second category.

In other words, the number of occupied child nodes (NN) of the reference child nodes may be determined based on the occupancy information (that is, whether being occupied) of the reference child nodes. Then, the local sparse category of the current child node can be determined based on a result of comparison between the NN and the first threshold. The first category may be a non-sparse category, and the second category may be a sparse category.

For example, a local sparse category of the child node 0 may be determined based on a number of occupied child nodes (NN) of twelve decoded child nodes adjacent to the current child node in the negative directions of x, y, and z axes in FIG. 8, where the number of occupied child nodes NN>1 indicates being non-sparse, and the number of occupied child nodes NN≤ 1 indicates being sparse. A local sparse category of the child node 1 may be determined based on a number of occupied child nodes (NN) of four decoded child nodes adjacent to the current child node in the negative direction (Front) of y-axis in FIG. 8, where the number of occupied child nodes NN>0 indicates being non-sparse, and the number of occupied child nodes NN=0 indicates being sparse. A local sparse category of the child node 2 may be determined based on a number of occupied child nodes (NN) of four decoded child nodes adjacent to the current child node in the negative direction (Bottom) of z-axis in FIG. 8, where the number of occupied child nodes NN>0 indicates being non-sparse, and the number of occupied child nodes NN=0 indicates being sparse. Local sparsity category of the child node 3 may be determined based on an NN of seven nodes including three nodes bit0+bit1+bit2 and four decoded nodes adjacent to the current child node in the negative direction (Left) of x-axis in FIG. 8, where the number of occupied child nodes NN>1 indicates being non-sparse, and the number of occupied child nodes NN≤ 1 indicates being sparse.

In addition, local sparsity category of the child node 4 may be determined based on an NN of twelve nodes including four nodes bit0+bit1+bit2+bit3 (denoted as “new Left”), four decoded nodes adjacent to the current child node in the negative direction (Front) of y-axis, and four decoded nodes adjacent to the current child node in the negative direction (Bottom) of z-axis in FIG. 8, where the number of occupied child nodes NN>1 indicates being non-sparse, and the number of occupied child nodes NN≤1 indicates being sparse. Local sparsity category of the child node 5 may be determined based on an NN of child nodes adjacent to the current child node in the negative direction (Front) of y-axis in FIG. 8, where the number of occupied child nodes NN>0 indicates being non-sparse, and the number of occupied child nodes NN=0 indicates being sparse. Local sparsity category of the child node 6 may be determined based on an NN of child nodes adjacent to the current child node in the negative direction (Bottom) of z-axis in FIG. 8, where the number of occupied child nodes NN>0 indicates being non-sparse, and the number of occupied child nodes NN=0 indicates being sparse. Local sparsity category of the child node 7 may be determined based on an NN of seven nodes including bit0+bit1+bit2+bit3+bit4+bit5+bit6, where the number of occupied child nodes NN>1 indicates being non-sparse, and the number of occupied child nodes NN≤ 1 indicates being sparse. This is not specifically limited in this application.

It may be understood that, when the current child node is the zeroth child node or the fourth child node, identifier information of the first target bit of the current child node refers to identifier information in the first category (namely, non-sparse), and may also be referred to as header information herein.

In some embodiments, when the current child node is the zeroth child node, the determining the identifier information of the first target bit of the current child node based on the occupancy information of the reference child nodes may include:
determining, based on occupancy information of a decoded child node adjacent to the zeroth child node in a first preset direction, identifier information of an m^{th} bit of the zeroth child node in a case of a first category;
determining, based on occupancy information of a decoded child node adjacent to the zeroth child node in a second preset direction, identifier information of an (m−1)^{th} bit of the zeroth child node in the case of the first category; and
determining, based on occupancy information of a decoded child node adjacent to the zeroth child node in a third preset direction, identifier information of the (m−2)^{th} bit of the zeroth child node in the case of the first category,

Herein m is a highest bit number of the zeroth child node in the case of the first category.

In embodiments of this application, the first preset direction may be a left direction from the zeroth child node, the second preset direction may be a front direction from the zeroth child node, and the third preset direction may be a bottom direction from the zeroth child node.

In other words, in the zeroth child node, the identifier information of the m^{th} bit may be determined depending on whether occupancy occurs in four child nodes in the left direction. If occupancy occurs in none of the four child nodes in the left direction, the identifier information of the m^{th} bit is set to 0; otherwise, the identifier information of the m^{th} bit is set to 1. The identifier information of the (m−1)^{th} bit may be determined depending on whether occupancy occurs in four child nodes in the front direction. If occupancy occurs in none of the four child nodes in the front direction, the identifier information of the (m−1)^{th} bit is set to 0; otherwise, the identifier information of the (m−1)^{th} bit is set to 1. The identifier information of the (m−2)^{th} bit may be determined depending on whether occupancy occurs in four child nodes in the bottom direction. If occupancy occurs in none of the four child nodes in the bottom direction, the identifier information of the (m−2)^{th} bit is set to 0; otherwise, the identifier information of the (m−2)^{th} bit is set to 1.

For example, for the zeroth child node (namely, child node 0), three bits of identifier information (in an order from higher bit to lower bit) in the non-sparse category are respectively adjusted as the interpretation shown in Table 9.

TABLE 9

| b₂ | b₁ | b₀ |
|---|---|---|
| being 0 if occupancy | being 0 if occupancy | being 0 if occupancy |
| occurs in none | occurs in none | occurs in none |
| of the four child | of the four child | of the four child |
| nodes in the left | nodes in the front | nodes in the bottom |
| direction, and being 1 | direction, and being 1 | direction, and being 1 |
| otherwise. | otherwise. | otherwise. |

In this way, Table 10 shows corrected context information of a child node 0 according to an embodiment of this application. The gray-filled part corresponds to the three-bit identifier information to which an actual meaning is assigned. In Table 10, three directions refer to the left direction, the front direction, and the bottom direction. Two directions refer to the left direction and the bottom direction; the front direction and the bottom direction, and the left direction and the front direction. One direction refers to the left direction, the front direction, or the bottom direction.

In some embodiments, when the current child node is the fourth child node, the determining the identifier information of the first target bit of the current child node based on the occupancy information of the reference child nodes may include:
determining identifier information of an nth bit of the fourth child node in a case of a first category based on occupancy information of decoded child nodes adjacent to the fourth child node in a fourth preset direction, a second preset direction, and a third preset direction;
determining identifier information of an (n−1)^{th} bit of the fourth child node in the case of the first category based on occupancy information of a decoded child node adjacent to the fourth child node in the fourth preset direction;
determining identifier information of an (n−2)^{th} bit of the fourth child node in the case of the first category based on occupancy information of a decoded child node adjacent to the fourth child node in the second preset direction; and
determining identifier information of an (n−3)^{th} bit of the fourth child node in the case of the first category based on occupancy information of a decoded child node adjacent to the fourth child node in the third preset direction.

Herein n is a highest bit number of the fourth child node in the case of the first category.

In embodiments of this application, the fourth preset direction may be a left direction formed based on the zeroth child node, the first child node, the second child node, and the third child node, the second preset direction may be the front direction from the fourth child node, and the third preset direction may be the bottom direction from the fourth child node.

In embodiments of this application, for the fourth child node, the zeroth child node, the first child node, the second child node, and the third child node may form a “new left direction” of the fourth child node. In other words, the identifier information of the nth bit may be determined depending on whether occupancy occurs in each of the new left direction, the front direction, and the bottom direction. If occupancy occurs in each of the new left direction, the front direction, and the bottom direction, the identifier information of the nth bit is set to 1; otherwise, the identifier information of the nth bit is set to 0. The identifier information of the (n−1)^{th} bit may be determined depending on whether occupancy occurs in four child nodes in the new left direction. If occupancy occurs in none of the four child nodes in the new left direction, the identifier information of the (n−1)^{th} bit is set to 0; otherwise, the identifier information of the (n−1)^{th} bit is set to 1. The identifier information of the (n−2)^{th} bit may be determined depending on whether occupancy occurs in four child nodes in the front direction. If occupancy occurs in none of the four child nodes in the front direction, the identifier information of the (n−2)^{th} bit is set to 0; otherwise, the identifier information of the (n−2)^{th} bit is set to 1. The identifier information of the (n−3)^{th} bit may be determined depending on whether occupancy occurs in four child nodes in the bottom direction. If occupancy occurs in none of the four child nodes in the bottom direction, the identifier information of the (n−3)^{th} bit is set to 0; otherwise, the identifier information of the (n−3)^{th} bit is set to 1.

For example, for the fourth child node (namely, child node 4), four bits of identifier information (in an order from higher bit to lower bit) in the non-sparse category are respectively adjusted as the interpretation shown in Table 11. The four nodes “bit0+bit1+bit2+bit3” are denoted as “new Left”.

TABLE 11

| b3 | b2 | b1 | b0 |
|---|---|---|---|
| Being 1 if occupancy | Being 0 if | Being 0 if | Being 0 if |
| occurs in each of the | occupancy occurs | occupancy | occupancy |
| “new Left”, “Front”, | in none of four | occurs | occurs |
| and “Bottom” | child nodes | in none of | in none of |
| directions, | in the | the four | the four |
| and being | “new Left” | child nodes | child nodes |
| 0 otherwise. | direction; and | in the | in the |
| | being 1 | “Front” | “Bottom” |
| | otherwise. | direction, | direction, |
| | | and being 1 | and being 1 |
| | | otherwise. | otherwise. |

In this way, Table 12 shows corrected context information of a child node 4 according to an embodiment of this application. The gray-filled part corresponds to the four-bit identifier information to which an actual meaning is assigned.

It may be further understood that, when the current child node is any one of the first child node, the second child node, the third child node, the fifth child node, and the sixth child node, the corresponding identifier information of the second target bit may also be determined based on the occupancy information of the reference child nodes. In some embodiments, the determining the identifier information of the second target bit of the current child node based on the occupancy information of the reference child nodes when the current child node meets the second condition may include:
determining identifier information of a k1^{th} bit of the first child node in a case of a first category based on occupancy information of a decoded child node adjacent to the first child node in a left direction; or
determining identifier information of a k2^{th} bit of the second child node in a case of a first category based on occupancy information of a decoded child node adjacent to the second child node in a left direction; or
determining identifier information of a k3^{th} bit of the third child node in a case of a second category based on occupancy information of the zeroth child node, the first child node, and the second child node; or
determining identifier information of a k4^{th} bit of the fifth child node based on occupancy information of the zeroth child node, the first child node, the second child node, and the third child node; or
determining identifier information of a k5^{th} bit of the sixth child node in a case of a first category based on occupancy information of the zeroth child node, the first child node, the second child node, and the third child node.

In embodiments of this application, k1, k2, k3, k4, and k5 are all positive integers. In a specific embodiment, the method may further include: setting a value of each of k1, k2, k4, and k5 to 16; and setting a value of k3 to 17.

In a specific implementation, for the first child node (namely, child node 1), identifier information of a 16^{th} bit (b₁₆) in the non-sparse category may be determined based on an occupancy status of four child nodes in the Left direction. If occupancy occurs in none of the four child nodes in the Left direction, the identifier information of the 16^{th} bit is set to 0; otherwise, the identifier information of the 16^{th} bit is set to 1. In this way, Table 13 shows corrected context information of a child node 1 according to an embodiment of this application. The gray-filled part corresponds to identifier information to which an actual meaning is assigned.

In a specific implementation, for the second child node (namely, child node 2), identifier information of a 16^{th} bit (b₁₆) in the non-sparse category may be determined based on an occupancy status of four child nodes in the Left direction. If occupancy occurs in none of the four child nodes in the Left direction, the identifier information of the 16^{th} bit is set to 0; otherwise, the identifier information of the 16^{th} bit is set to 1. In this way, Table 14 shows corrected context information of a child node 2 according to an embodiment of this application. The gray-filled part corresponds to identifier information to which an actual meaning is assigned.

In a specific implementation, for the third child node (namely, child node 3), identifier information of a 17^{th} bit (b₁₇) in the non-sparse category may be determined based on an occupancy status of the three child nodes bit0+bit1+bit2. If occupancy occurs in none of the three child nodes bit0+bit1+bit2, the identifier information of the 17^{th} bit is set to 0; otherwise, the identifier information of the 17^{th} bit is set to 1. In this way, Table 15 shows corrected context information of a child node 3 according to an embodiment of this application. The gray-filled part corresponds to identifier information to which an actual meaning is assigned.

In a specific implementation, for the fifth child node (namely, child node 5), identifier information of a 16^{th} bit (b₁₆) in the non-sparse category may be determined based on an occupancy status of four child nodes in the new Left direction. If occupancy occurs in none of the four child nodes in the new Left direction, the identifier information of the 16^{th} bit is set to 0; otherwise, the identifier information of the 16^{th} bit is set to 1. The four child nodes in the new Left direction are formed by bit0+bit1+bit2+bit3. In this way, Table 16 shows corrected context information of a child node 5 according to an embodiment of this application. The gray-filled part corresponds to identifier information to which an actual meaning is assigned.

In a specific implementation, for the sixth child node (namely, child node 6), identifier information of a 16^{th} bit (b₁₆) in the non-sparse category may be determined based on an occupancy status of four child nodes in the new Left direction. If occupancy occurs in none of the four child nodes in the new Left direction, the identifier information of the 16^{th} bit is set to 0; otherwise, the identifier information of the 16^{th} bit is set to 1. The four child nodes in the new Left direction are formed by bit0+bit1+bit2+bit3. In this way, Table 17 shows corrected context information of a child node 6 according to an embodiment of this application. The gray-filled part corresponds to identifier information to which an actual meaning is assigned.

It should be further noted that, in embodiments of this application, if the current child node meets the second condition, that is, when the current child node is any one of the first child node, the second child node, the third child node, the fifth child node, and the sixth child node, an identifier policy for the identifier information of the second target bit of the current child node is different from that in a related technology. Therefore, in some embodiments, the method may further include: adjusting the identifier policy of the second target bit to determine the identifier information of the second target bit of the current child node.

The identifier policy of the related technology is that 1 indicates being unoccupied and 0 indicates being occupied according to an occupancy status of a corresponding reference child node. The identifier policy in embodiments of this application is that 0 indicates being unoccupied and 1 indicates being occupied according to an occupancy status of a corresponding reference child node. Therefore, the identifier information of the second target bit of the current child node may alternatively be obtained by performing a negation operation on the second target bit in the related technology. In some embodiments, the method may further include:
determining initial identifier information of the second target bit of the current child node; and
performing a negation operation on the initial identifier information to determine the identifier information of the second target bit of the current child node.

In other words, in an example of the child node 1, the identifier information of the 16^{th} bit (b₁₆) in the non-sparse category is determined based on an occupancy status of four child nodes in Left direction the related technology; however, in this case, 1 indicates being unoccupied and 0 indicates that occupancy occurs, which causes a decoded symbol bit losing its original meaning. Therefore, in embodiments of this application, a symbol, of the 16^{th} bit (b₁₆) in the non-sparse category, indicating the occupancy status of the four child nodes in the Left direction may be corrected as follows: 0 indicates being unoccupied and 1 indicates being occupied, which is equivalent to that a negation operation is performed on the identifier information in the related technology. In an example of the child node 3, identifier information of a 17^{th} bit (b₁₇) in the sparse category is determined based on an occupancy status of three child nodes bit0+bit1+bit2 in the related technology; however, in this case, 1 indicates being unoccupied and 0 indicates being occupied, which causes a decoded symbol bit losing its original meaning. Therefore, in embodiments of this application, a symbol, of the 17th bit (b₁₇) in the sparse category, indicating the occupancy status of the three child nodes bit0+bit1+bit2 may be corrected as follows: 0 indicates being unoccupied and 1 indicates being occupied, which is equivalent to that a negation operation is performed on the identifier information in the related technology.

It should be further noted that, in embodiments of this application, for context information in the related technology, a negation operation for some bits causes decoded symbols in the context information to be invalid. Therefore, correction processing may be performed on a third target bit processed by a negation operation in the context information. Therefore, in some embodiments, the method may further include: performing correction processing on a third target bit processed by a negation operation in the context information, to determine identifier information of the third target bit in the context information.

In a specific embodiment, the correction processing herein may be canceling the negation operation performed on the third target bit, so as to ensure validity of a decoded symbol in the context information.

For example, still in an example of the child node 1, Table 18 shows bits (dot-filled part) processed by a negation operation in the context information of the child node 1, and Table 19 shows corrected context information of the child node 1 according to an embodiment of this application. The dot-filled parts corresponds to the identifier information for which the negation operation is cancelled.

It should be further noted that, in embodiments of this application, for the seventh child node (namely, child node 7), the identifier information herein is not adjusted for any of the non-sparse category and sparse category. In addition, the negation operation in the context information is not corrected.

S1003: The context information of the current child node is determined based on the preset identifier information.

S1004: A to-be-decoded syntax element of the current child node is decoded based on the context information, to determine a value of the to-be-decoded syntax element.

It should be noted that, except for the seventh child node, context information of remaining seven child nodes including the zeroth child node, the first child node, the second child node, the third child node, the fourth child node, the fifth child node, and the sixth child node are sequentially presented below with reference to Table 20 to Table 26 after the foregoing technical solution. The dot-filled part corresponds to the identifier information for which the negation operation is cancelled.

It should be further noted that, in some embodiments, the method may further include: adjusting a position of the preset identifier information in the context information.

In embodiments of this application, the context information may include primary information and secondary information, and a priority of the primary information is higher than that of the secondary information. Therefore, in the context information, the primary information is arranged at a relatively higher position than the secondary information. Herein, a position of the preset identifier information may be adjusted based on a priority of the context information, that is, if the preset identifier information is not very important, the preset identifier information may be adjusted to a relatively low position.

It should be further noted that, in some embodiments, the method may further include: adjusting a use mode of a decoded syntax element in the context information.

In embodiments of this application, in an example of the child node 1, identifier information of a 16^{th} bit (b₁₆) in the non-sparse category may be determined based on an occupancy status of four child nodes in the Left direction. In other words, the four child nodes herein are used as a whole to determine the identifier information. However, eight child nodes and twelve child nodes may also be used as a whole to determine the identifier information, which is not limited herein.

It should be further noted that, after the context information is determined, a target data processing mode (namely, a target decoder) may be further determined based on the context information, and then a to-be-decoded syntax element is decoded based on target data processing mode, to obtain a value of the to-be-decoded syntax element.

An embodiment provides a decoding method, including: determining occupancy information of reference child nodes of a current child node; determining preset identifier information of the current child node based on the occupancy information of the reference child nodes; determining context information of the current child node based on the preset identifier information; and decoding a to-be-decoded syntax element of the current child node based on the context information, to determine a value of the to-be-decoded syntax element. In this way, an actual meaning can be assigned to the identifier information in the context information, and a decoded symbol bit can be made valid. Thus, accuracy of constructed context information can be improved to select an optimal target data processing mode for decoding. In this way, coding performance can be maintained, and coding efficiency can also be improved.

FIG. 11 is a schematic flowchart of an encoding method according to another embodiment of this application. As shown in FIG. 11, the method may include S1101 to S1104.

S1101: Occupancy information of reference child nodes of a current child node is determined.

It should be noted that the encoding method in embodiments of this application is applied to an encoder (or referred to as “entropy encoder”). In addition, the encoding method may specifically refer to a point cloud encoding method, or a point cloud entropy encoding method. More specifically, an embodiment of this application provides a context adjustment method, to make identifier information in context information have actual meaning, and may further make an encoded symbol bit be valid.

It should be further noted that, in an example of a G-PCC encoder shown in FIG. 2, the method in embodiments of this application is used to construct context information of the current child node, which is then applied to the part of entropy encoding (namely, the bold part in FIG. 2). Therefore, by improving accuracy of the constructed context information, performance of encoding a point cloud can be improved.

It should be further noted that, in a point cloud, points may refer to all points in the point cloud, or may refer to some points in the point cloud relatively centralized in space. A current node may refer to a node currently to be encoded in the point cloud. The current node may include eight child nodes, and then to-be-encoded child nodes located at different locations of the current node are sequentially used as a current child node according to a preset scanning order (as shown in FIG. 7), so as to construct context information for the current child node, and encode a to-be-encoded syntax element of the current child node.

It should be understood that, in embodiments of this application, a reference child node refers to a co-planar neighbor node, a co-edge neighbor node, or a co-point neighbor node that is adjacent to the current child node. In some embodiments, the reference child nodes may include at least one of the following:
an encoded sibling node of the current child node;
an encoded child node adjacent to the current child node in a first preset direction;
an encoded child node adjacent to the current child node in a second preset direction;
an encoded child node adjacent to the current child node in a third preset direction; or
an encoded child node adjacent to the current child node in a fourth preset direction.

It should be noted that, in embodiments of this application, the first preset direction may refer to a negative direction (Left direction) of the x-axis of the current child node, the second preset direction may refer to a negative direction (Front direction) of a y-axis of the current child node, and the third preset direction may refer to a negative direction (Bottom direction) of a z-axis of the current child node. In addition, it should be noted that the fourth preset direction exists only when the current child node is the child node 4, the child node 5, the child node 6, or the child node 7. In this case, the fourth preset direction may refer to a new left direction formed by the child node 0, the child node 1, the child node 2, and the child node 3.

It should be further noted that, in embodiments of this application, the child node 0 may be represented by bit0, the child node 1 may be represented by bit1, the child node 2 may be represented by bit2, the child node 3 may be represented by bit3, the child node 4 may be represented by bit4, the child node 5 may be represented by bit5, the child node 6 may be represented by bit6, and the child node 7 may be represented by bit6.

Regarding the encoded sibling node of the current child node, if the current child node is the child node 0, no encoded sibling node exists; if the current child node is the child node 1, the encoded sibling node is bit0; if the current child node is the child node 2, the encoded sibling nodes are bit0 and bit1; if the current child node is the child node 3, the encoded sibling nodes are bit0, bit1, and bit2; if the current child node is the child node 4, the encoded sibling nodes are bit0, bit1, bit2, and bit3. By analogy, if the current child node is the child node 7, the encoded sibling nodes are bit0, bit1, bit2, bit3, bit4, bit5, and bit6.

For example, if the current child node is the child node 0, the reference child nodes may include a coplanar child node neighbor, a co-edge child node neighbor, and a co-point child node neighbor, include no encoded sibling node, and include a coplanar parent node neighbor, and an encoded neighbor in 20 other neighbors that can be referenced; if the current child node is the child node 1, the reference child nodes may include a coplanar child node neighbor, a co-edge child node neighbor, and a co-point child node neighbor, include one encoded sibling node bit0, and include a coplanar parent node neighbor, and an encoded neighbor in 20 other neighbors that can be referenced; if the current child node is the child node 2, the reference child nodes may include a coplanar child node neighbor, a co-edge child node neighbor, and a co-point child node neighbor, include two encoded sibling nodes bit0 and bit1, and include a coplanar parent node neighbor, and an encoded neighbor in 20 other neighbors that can be referenced; if the current child node is the child node 3, the reference child nodes may include a coplanar child node neighbor, a co-edge child node neighbor, and a co-point child node neighbor, include three encoded sibling nodes bit0, bit1, and bit2, and include a coplanar parent node neighbor, and an encoded neighbor in 20 other neighbors that can be referenced; if the current child node is the child node 4, the reference child nodes may include a coplanar child node neighbor, a co-edge child node neighbor, and a co-point child node neighbor, include four encoded sibling nodes bit0, bit1, bit2, and bit3, and include a coplanar parent node neighbor, and an encoded neighbor in 20 other neighbors that can be referenced; if the current child node is the child node 5, the reference child nodes may include a coplanar child node neighbor, a co-edge child node neighbor, and a co-point child node neighbor, include five encoded sibling nodes bit0, bit1, bit2, bit3, and bit4, and include a coplanar parent node neighbor, and an encoded neighbor in 20 other neighbors that can be referenced; if the current child node is the child node 6, the reference child nodes may include a coplanar child node neighbor, a co-edge child node neighbor, and a co-point child node neighbor, include six encoded sibling nodes bit0, bit0, bit1, bit2, bit3, bit4, and bit5, and include a coplanar parent node neighbor, and an encoded neighbor in 20 other neighbors that can be referenced; if the current child node is the child node 7, the reference child nodes may include seven encoded sibling nodes bit0, bit0, bit1, bit2, bit3, bit4, bit5, and bit6, and include a coplanar parent node neighbor, and an encoded neighbor in 20 other neighbors that can be referenced. Herein, the child node 7 has no coplanar child node neighbor, co-edge child node neighbor, or co-point child node neighbor.

It should be further understood that, in embodiments of this application, occupancy information of a reference child node is used to indicate whether the reference child node is occupied by a point. For example, if the occupancy information of the reference child node is 1, it may indicate that the reference child node is occupied; if the occupancy information of the reference child node is 0, it may indicate that the reference child node is not occupied by any point.

S1102: Preset identifier information of the current child node is determined based on the occupancy information of the reference child nodes.

It should be noted that, in embodiments of this application, an actual meaning can be assigned to the preset identifier information in the context information of the current child node. Specifically, the value of the preset identifier information may be determined based on occupancy information of the reference child nodes. In some embodiments, the determining the preset identifier information of the current child node based on the occupancy information of the reference child nodes may include:
determining identifier information of a first target bit of the current child node based on the occupancy information of the reference child nodes when the current child node meets a first condition; or
determining identifier information of a second target bit of the current child node based on the occupancy information of the reference child nodes when the current child node meets a second condition.

In embodiments of this application, the current child node meeting the first condition may include that the current child node is either a zeroth child node or a fourth child node;

In embodiments of this application, the current child node meeting the second condition may include that the current child node is one of a first child node, a second child node, a third child node, a fifth child node, and a sixth child node.

The zeroth child node (bit0), the first child node (bit1), the second child node (bit2), the third child node (bit3), the fourth child node (bit4), the fifth child node (bit5), and the sixth child node (bit6) are sequentially child nodes to be encoded in sequence according to a preset scanning order in the current node. For example, the preset scanning order may be the scanning order shown in FIG. 7.

It should be further noted that, in embodiments of this application, a local sparse category of the current child node may be further determined based on the occupancy information of the reference child nodes. In some embodiments, the method may further include:
determining a number of occupied child nodes of the reference child nodes based on the occupancy information of the reference child nodes; and
determining a local sparse category of the current child node based on the number of occupied child nodes of the reference child nodes.

Further, in some embodiments, the determining the local sparse category of the current child node based on the number of occupied child nodes of the reference child nodes may include:
in a case that the number of occupied child nodes of the reference child nodes is greater than a first threshold, determining that the local sparse category of the current child node is a first category;
in a case that the number of occupied child nodes of the reference child nodes is less than or equal to a first threshold, determining that the local sparse category of the current child node is a second category.

In other words, the number of occupied child nodes (NN) of the reference child nodes may be determined based on the occupancy information (that is, whether being occupied) of the reference child nodes. Then, the local sparse category of the current child node can be determined based on a result of comparison between the NN and the first threshold. The first category may be a non-sparse category, and the second category may be a sparse category.

For example, a local sparse category of the child node 0 may be determined based on a number of occupied child nodes (NN) of twelve encoded child nodes adjacent to the current child node in the negative directions of x, y, and z axes in FIG. 8, where the number of occupied child nodes NN>1 indicates being non-sparse, and the number of occupied child nodes NN≤1 indicates being sparse. A local sparse category of the child node 1 may be determined based on a number of occupied child nodes (NN) of four encoded child nodes adjacent to the current child node in the negative direction (Front) of y-axis in FIG. 8, where the number of occupied child nodes NN>0 indicates being non-sparse, and the number of occupied child nodes NN=0 indicates being sparse. A local sparse category of the child node 2 may be determined based on a number of occupied child nodes (NN) of four encoded child nodes adjacent to the current child node in the negative direction (Bottom) of z-axis in FIG. 8, where the number of occupied child nodes NN>0 indicates being non-sparse, and the number of occupied child nodes NN=0 indicates being sparse. Local sparsity category of the child node 3 may be determined based on an NN of seven nodes including three nodes bit0+bit1+bit2 and four encoded nodes adjacent to the current child node in the negative direction (Left) of x-axis in FIG. 8, where the number of occupied child nodes NN>1 indicates being non-sparse, and the number of occupied child nodes NN≤ 1 indicates being sparse.

In addition, local sparsity category of the child node 4 may be determined based on an NN of twelve nodes including four nodes bit0+bit1+bit2+bit3 (denoted as “new Left”), four encoded nodes adjacent to the current child node in the negative direction (Front) of y-axis, and four encoded nodes adjacent to the current child node in the negative direction (Bottom) of z-axis in FIG. 8, where the number of occupied child nodes NN>1 indicates being non-sparse, and the number of occupied child nodes NN≤1 indicates being sparse. Local sparsity category of the child node 5 may be determined based on an NN of child nodes adjacent to the current child node in the negative direction (Front) of y-axis in FIG. 8, where the number of occupied child nodes NN>0 indicates being non-sparse, and the number of occupied child nodes NN=0 indicates being sparse. Local sparsity category of the child node 6 may be determined based on an NN of child nodes adjacent to the current child node in the negative direction (Bottom) of z-axis in FIG. 8, where the number of occupied child nodes NN>0 indicates being non-sparse, and the number of occupied child nodes NN=0 indicates being sparse. Local sparsity category of the child node 7 may be determined based on an NN of seven nodes including bit0+bit1+bit2+bit3+bit4+bit5+bit6, where the number of occupied child nodes NN>1 indicates being non-sparse, and the number of occupied child nodes NN≤1 indicates being sparse. This is not specifically limited in this application.

It may be understood that, when the current child node is the zeroth child node or the fourth child node, identifier information of the first target bit of the current child node refers to identifier information in the first category (namely, non-sparse), and may also be referred to as header information herein.

In some embodiments, when the current child node is the zeroth child node, the determining the identifier information of the first target bit of the current child node based on the occupancy information of the reference child nodes may include:
determining, based on occupancy information of an encoded child node adjacent to the zeroth child node in a first preset direction, identifier information of an m^{th} bit of the zeroth child node in a case of a first category;
determine, based on occupancy information of an encoded child node adjacent to the zeroth child node in a second preset direction, identifier information of an (m−1) th bit of the zeroth child node in the case of the first category; and
determine, based on occupancy information of an encoded child node adjacent to the zeroth child node in a third preset direction, identifier information of an (m−2)^{th} bit of the zeroth child node in the case of the first category.

Herein m is a highest bit number of the zeroth child node in the case of the first category.

In embodiments of this application, the first preset direction may be a left direction from the zeroth child node, the second preset direction may be a front direction from the zeroth child node, and the third preset direction may be a bottom direction from the zeroth child node.

In other words, in the zeroth child node, the identifier information of the m^{th} bit may be determined depending on whether occupancy occurs in four child nodes in the left direction. If occupancy occurs in none of the four child nodes in the left direction, the identifier information of the m^{th} bit is set to 0; otherwise, the identifier information of the m^{th} bit is set to 1. The identifier information of the (m−1)^{th} bit may be determined depending on whether occupancy occurs in four child nodes in the front direction. If occupancy occurs in none of the four child nodes in the front direction, the identifier information of the (m−1)^{th} bit is set to 0; otherwise, the identifier information of the (m−1)^{th} bit is set to 1. The identifier information of the (m−2)^{th} bit may be determined depending on whether occupancy occurs in four child nodes in the bottom direction. If occupancy occurs in none of the four child nodes in the bottom direction, the identifier information of the (m−2)^{th} bit is set to 0; otherwise, the identifier information of the (m−2)^{th} bit is set to 1.

For example, for the zeroth child node (namely, child node 0), three bits of identifier information (in an order from higher bit to lower bit) in the non-sparse category are respectively adjusted as shown in Table 9. In this way, Table 10 shows corrected context information of a child node 0 according to an embodiment of this application. The gray-filled part corresponds to the three-bit identifier information to which an actual meaning is assigned.

In some embodiments, when the current child node is the fourth child node, the determining the identifier information of the first target bit of the current child node based on the occupancy information of the reference child nodes may include:
determining identifier information of an nth bit of the fourth child node in a case of a first category based on occupancy information of encoded child nodes adjacent to the fourth child node in a fourth preset direction, a second preset direction, and a third preset direction;
determining identifier information of an (n−1)^{th} bit of the fourth child node in the case of the first category based on occupancy information of an encoded child node adjacent to the fourth child node in the fourth preset direction;
determining identifier information of an (n−2)^{th} bit of the fourth child node in the case of the first category based on occupancy information of an encoded child node adjacent to the fourth child node in the second preset direction; and
determining identifier information of an (n−3)^{th} bit of the fourth child node in the case of the first category based on occupancy information of an encoded child node adjacent to the fourth child node in the third preset direction.

Herein n is a highest bit number of the fourth child node in the case of the first category.

In embodiments of this application, the fourth preset direction may be a left direction formed based on the zeroth child node, the first child node, the second child node, and the third child node, the second preset direction may be the front direction from the fourth child node, and the third preset direction may be the bottom direction from the fourth child node.

In embodiments of this application, for the fourth child node, the zeroth child node, the first child node, the second child node, and the third child node may form a “new left direction” of the fourth child node. In other words, the identifier information of the nth bit may be determined depending on whether occupancy occurs in the new left direction, the front direction, and the bottom direction. If occupancy occurs in the new left direction, the front direction, and the bottom direction, the identifier information of the nth bit is set to 1; otherwise, the identifier information of the nth bit is set to 0. The identifier information of the (n−1)^{th} bit may be determined depending on whether occupancy occurs in four child nodes in the new left direction. If occupancy occurs in none of the four child nodes in the new left direction, the identifier information of the (n−1)^{th} bit is set to 0; otherwise, the identifier information of the (n−1)^{th} bit is set to 1. The identifier information of the (n−2)^{th} bit may be determined depending on whether occupancy occurs in four child nodes in the front direction. If occupancy occurs in none of the four child nodes in the front direction, the identifier information of the (n−2)^{th} bit is set to 0; otherwise, the identifier information of the (n−2)^{th} bit is set to 1. The identifier information of the (n−3)^{th} bit may be determined depending on whether occupancy occurs in four child nodes in the bottom direction. If occupancy occurs in none of the four child nodes in the bottom direction, the identifier information of the (n−3)^{th} bit is set to 0; otherwise, the identifier information of the (n−3)^{th} bit is set to 1.

For example, for the fourth child node (namely, child node 4), four bits of identifier information (in an order from higher bit to lower bit) in the non-sparse category are respectively adjusted as shown in Table 11. The four nodes “bit0+bit1+bit2+bit3” are denoted as “new Left”. In this way, Table 12 shows corrected context information of a child node 4 according to an embodiment of this application. The gray-filled part corresponds to the four-bit identifier information to which an actual meaning is assigned.

It may be further understood that, when the current child node is any one of the first child node, the second child node, the third child node, the fifth child node, and the sixth child node, the corresponding identifier information of the second target bit may also be determined based on the occupancy information of the reference child nodes. In some embodiments, the determining the identifier information of the second target bit of the current child node based on the occupancy information of the reference child nodes when the current child node meets the second condition may include:
determining identifier information of a k1^{th} bit of the first child node in a case of a first category based on occupancy information of an encoded child node adjacent to the first child node in a left direction; or
determining identifier information of a k2^{th} bit of the second child node in a case of a first category based on occupancy information of an encoded child node adjacent to the second child node in a left direction; or
determining identifier information of a k3^{th} bit of the third child node in a case of a second category based on occupancy information of the zeroth child node, the first child node, and the second child node; or
determining identifier information of a k4^{th} bit of the fifth child node based on occupancy information of the zeroth child node, the first child node, the second child node, and the third child node; or
determining identifier information of a k5^{th} bit of the sixth child node in a case of a first category based on occupancy information of the zeroth child node, the first child node, the second child node, and the third child node.

In embodiments of this application, k1, k2, k3, k4, and k5 are all positive integers. In a specific embodiment, the method may further include: setting a value of each of k1, k2, k4, and k5 to 16; and setting a value of k3 to 17.

In a specific implementation, for the first child node (namely, child node 1), identifier information of a 16^{th} bit (b₁₆) in the non-sparse category may be determined based on an occupancy status of four child nodes in the Left direction. If occupancy occurs in none of the four child nodes in the Left direction, the identifier information of the 16^{th} bit is set to 0; otherwise, the identifier information of the 16^{th} bit is set to 1. In this way, Table 13 shows corrected context information of a child node 1 according to an embodiment of this application. The gray-filled part corresponds to identifier information to which an actual meaning is assigned.

In a specific implementation, for the second child node (namely, child node 2), identifier information of a 16^{th} bit (b₁₆) in the non-sparse category may be determined based on an occupancy status of four child nodes in Left direction. If occupancy occurs in none of the four child nodes in the Left direction, the identifier information of the 16^{th} bit is set to 0; otherwise, the identifier information of the 16^{th} bit is set to 1. In this way, Table 14 shows corrected context information of a child node 2 according to an embodiment of this application. The gray-filled part corresponds to identifier information to which an actual meaning is assigned.

In a specific implementation, for the third child node (namely, child node 3), identifier information of a 17^{th} bit (b₁₇) in the non-sparse category may be determined based on an occupancy status of the three child nodes bit0+bit1+bit2. If occupancy occurs in none of the three child nodes bit0+bit1+bit2, the identifier information of the 17^{th} bit is set to 0; otherwise, the identifier information of the 17^{th} bit is set to 1. In this way, Table 15 shows corrected context information of a child node 3 according to an embodiment of this application. The gray-filled part corresponds to identifier information to which an actual meaning is assigned.

In a specific implementation, for the fifth child node (namely, child node 5), identifier information of a 16^{th} bit (b₁₆) in the non-sparse category may be determined based on an occupancy status of four child nodes in the new Left direction. If occupancy occurs in none of the four child nodes in the new Left direction, the identifier information of the 16^{th} bit is set to 0; otherwise, the identifier information of the 16^{th} bit is set to 1. The four child nodes in the new Left direction are formed by bit0+bit1+bit2+bit3. In this way, Table 16 shows corrected context information of a child node 5 according to an embodiment of this application. The gray-filled part corresponds to identifier information to which an actual meaning is assigned.

In a specific implementation, for the sixth child node (namely, child node 6), identifier information of a 16^{th} bit (b₁₆) in the non-sparse category may be determined based on an occupancy status of four child nodes in the new Left direction. If occupancy occurs in none of the four child nodes in the new Left direction, the identifier information of the 16^{th} bit is set to 0; otherwise, the identifier information of the 16^{th} bit is set to 1. The four child nodes in the new Left direction are formed by bit0+bit1+bit2+bit3. In this way, Table 17 shows corrected context information of a child node 6 according to an embodiment of this application. The gray-filled part corresponds to identifier information to which an actual meaning is assigned.

It should be further noted that, in embodiments of this application, if the current child node meets the second condition, that is, when the current child node is any one of the first child node, the second child node, the third child node, the fifth child node, and the sixth child node, an identifier policy for the identifier information of the second target bit of the current child node is different from that in a related technology. Therefore, in some embodiments, the method may further include: adjusting the identifier policy of the second target bit to determine the identifier information of the second target bit of the current child node.

The identifier policy of the related technology is that 1 indicates being unoccupied and 0 indicates being occupied according to an occupancy status of a corresponding reference child node. The identifier policy in embodiments of this application is that 0 indicates being unoccupied and 1 indicates being occupied according to an occupancy status of a corresponding reference child node. Therefore, the identifier information of the second target bit of the current child node may alternatively be obtained by performing a negation operation on the second target bit in the related technology. In some embodiments, the method may further include:
determining initial identifier information of the second target bit of the current child node; and
performing a negation operation on the initial identifier information to determine the identifier information of the second target bit of the current child node.

In other words, in an example of the child node 1, the identifier information of the 16^{th} bit (b₁₆) in the non-sparse category is determined based on an occupancy status of four child nodes in Left direction the related technology; however, in this case, 1 indicates being unoccupied and 0 indicates being occupied, which causes an encoded symbol bit losing its original meaning. Therefore, in embodiments of this application, a symbol, of the 16^{th} bit (b₁₆) in the non-sparse category, indicating the occupancy status of the four child nodes in the Left direction may be corrected as follows: 0 indicates being unoccupied and 1 indicates being occupied, which is equivalent to that a negation operation is performed on the identifier information in the related technology. In an example of the child node 3, identifier information of a 17^{th} bit (b₁₇) in the sparse category is determined based on an occupancy status of three child nodes bit0+bit1+bit2 in the related technology; however, in this case, 1 indicates being unoccupied and 0 indicates being occupied, which causes an encoded symbol bit losing its original meaning. Therefore, in embodiments of this application, a symbol, of the 17^{th} bit (b₁₇) in the sparse category, indicating the occupancy status of the three child nodes bit0+bit1+bit2 may be corrected as follows: 0 indicates being unoccupied and 1 indicates being occupied, which is equivalent to that a negation operation is performed on the identifier information in the related technology.

It should be further noted that, in embodiments of this application, for context information in the related technology, a negation operation for some bits causes encoded symbols in the context information to be invalid. Therefore, correction processing may be performed on a third target bit processed by a negation operation in the context information. Therefore, in some embodiments, the method may further include: performing correction processing on a third target bit processed by a negation operation in the context information, to determine identifier information of the third target bit in the context information.

In a specific embodiment, the correction processing herein may be cancelling the negation operation performed on the third target bit, so as to ensure validity of an encoded symbol in the context information.

For example, still in an example of the child node 1, Table 18 shows bits processed by a negation operation in the context information of the child node 1, and Table 19 shows context information of the corrected child node 1 according to an embodiment of this application. The dot-filled part corresponds to the identifier information for which the negation operation is cancelled.

It should be further noted that, in embodiments of this application, for the seventh child node (namely, child node 7), the identifier information herein is not adjusted for any of the non-sparse category and sparse category. In addition, the negation operation in the context information is not corrected.

S1103: The context information of the current child node is determined based on the preset identifier information.

S1104: A value of a to-be-encoded syntax element of the current child node is encoded based on the context information, and an encoded bit is written into a bitstream.

It should be noted that, except for the seventh child node, context information of remaining seven child nodes including the zeroth child node, the first child node, the second child node, the third child node, the fourth child node, the fifth child node, and the sixth child node are sequentially presented in Table 20 to Table 26 after the foregoing technical solution. The dot-filled part corresponds to the identifier information for which the negation operation is cancelled.

It should be further noted that, in some embodiments, the method may further include: adjusting a position of the preset identifier information in the context information.

In embodiments of this application, the context information may include primary information and secondary information, and a priority of the primary information is higher than that of the secondary information. Therefore, in the context information, the primary information is arranged at a relatively higher position than the secondary information. Herein, a position of the preset identifier information may be adjusted based on a priority of the context information, that is, if the preset identifier information is not very important, the preset identifier information may be adjusted to a relatively low position.

It should be further noted that, in some embodiments, the method may further include: adjusting a use mode of an encoded syntax element in the context information.

In embodiments of this application, in an example of the child node 1, identifier information of a 16^{th} bit (b₁₆) in the non-sparse category may be determined based on an occupancy status of four child nodes in the Left direction. In other words, the four child nodes herein are used as a whole to determine the identifier information. However, eight child nodes and twelve child nodes may also be used as a whole to determine the identifier information, which is not limited herein.

It should be further noted that, after the context information is determined, a target data processing mode (namely, a target encoder) may be further determined based on the context information, then a value of a to-be-encoded syntax element is encoded based on the target data processing mode, and an obtained encoded bit is written into a bitstream.

Further, an embodiment of this application further provides a bitstream, where the bitstream is generated by performing bit encoding on to-be-encoded information; and the to-be-encoded information at least includes a value of a to-be-encoded syntax element of a current child node.

It should be further noted that, in embodiments of this application, the to-be-encoded syntax element of the current child node may be encoded on an encoding side and then written into the bitstream. Subsequently, the value of the syntax element may be determined by decoding on a decoding side, so that a related decoding operation is executed on the decoding side by using the value of the syntax element.

An embodiment provides an encoding method, including: determining occupancy information of reference child nodes of a current child node; determining preset identifier information of the current child node based on the occupancy information of the reference child nodes; determining context information of the current child node based on the preset identifier information; and encoding a value of a to-be-encoded syntax element of the current child node based on the context information, and writing an encoded bit into a bitstream. In this way, an actual meaning can be assigned to the identifier information in the context information, and an encoded symbol bit can be made valid. Thus, accuracy of constructed context information can be improved to select an optimal target encoder for encoding. In this way, coding performance can be maintained, and coding efficiency can also be improved.

In still another embodiment of this application, for the context adjustment method provided in embodiments of this application, compared with a related technology, there are two modifications:

(1) Modifying identifier information in an existing context to assign an actual meaning For the child node 0, three bits of identifier information (in an order from higher bit to lower bit) in the non-sparse category are respectively adjusted as shown in Table 9; and correspondingly, corrected context information of the child node 0 is as shown in Table 10.

For the child node 1, a symbol of a 16^{th} bit (b₁₆) indicating an occupancy status of four child nodes in the Left direction in the non-sparse category is corrected to that 0 indicates being unoccupied and 1 indicates being occupied. Correspondingly, the corrected context information of the child node 1 is as shown in Table 13.

For the child node 2, a symbol of a 16^{th} bit (b₁₆) indicating an occupancy status of four child nodes in the Left direction in the non-sparse category is corrected to that 0 indicates being unoccupied and 1 indicates being occupied. Correspondingly, the corrected context information of the child node 2 is as shown in Table 14.

For the child node 3, a symbol a 17^{th} bit (b₁₇) indicating an occupancy status of three child nodes bit0+bit1+bit2 in the sparse category is corrected to that 0 indicates being unoccupied and 1 indicates being occupied. Correspondingly, the corrected context information of the child node 3 is as shown in Table 15.

For the child node 4, four bits of identifier information (in an order from higher for lower bit) in the non-sparse category are respectively adjusted as shown in Table 11, where the four nodes bit0+bit1+bit2+bit3 are denoted as “new Left”; and correspondingly, corrected context information of the child node 4 is as shown in Table 12.

For the child node 5, a symbol of a 16^{th} bit (b₁₆) indicating an occupancy status of four child nodes in the “new Left” direction in the non-sparse category is corrected to that 0 indicates being unoccupied and 1 indicates being occupied; and correspondingly, the corrected context information of the child node 5 is as shown in Table 16.

For the child node 6, a symbol of a 16^{th} bit (b₁₆) indicating an occupancy status for four child nodes in the “new Left” direction in the non-sparse category is corrected to that 0 indicates being unoccupied and 1 indicates being occupied; and correspondingly, the corrected context information of the child node 6 is as shown in Table 17.

For the child node 7, no adjustment is made to the bits of identifier information in the non-sparse category or the sparse category.

(2) Modifying a negation operation on an encoded syntax element in an existing context

The negation operation is corrected by using context information of the child node 1 as an example. For details, refer to Table 18 and Table 19. In addition, the same correction is made on other child nodes except for the child node 7.

With the combination of foregoing two correction solutions of the context information, Table 20 to Table 26 sequentially shows final context information of the seven child nodes (excluding the child node 7). The dot-filled part corresponds to the identifier information for which the negation operation is cancelled.

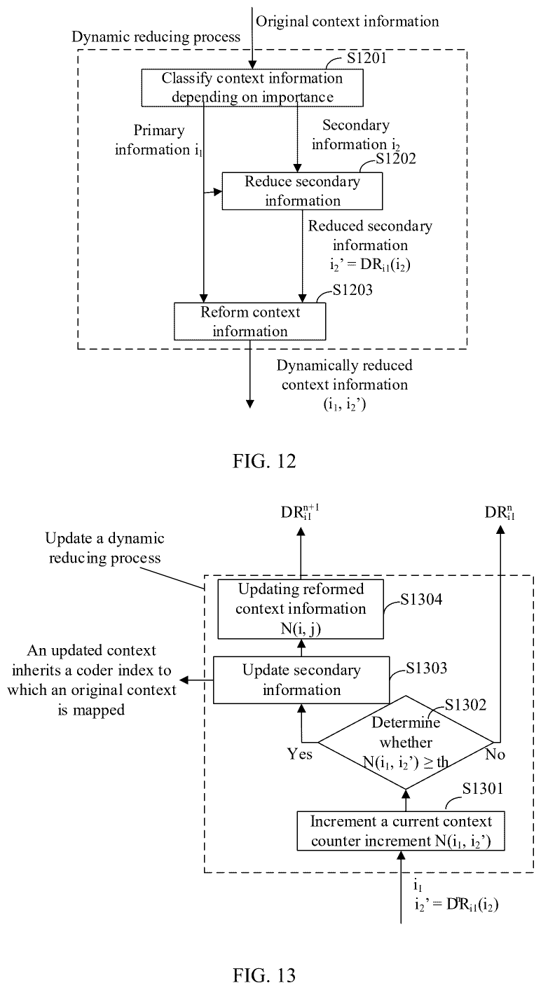

Further, in embodiments of this application, the context information may be further dynamically reduced or a dynamical reduction process may be updated. FIG. 12 is a schematic diagram of a procedure for dynamic reduction of context information according to an embodiment of this application. As shown in FIG. 12, the procedure may include the following steps:
S1201: classifying context information depending on importance;
S1202: reducing secondary information to obtain reduced secondary information; and
S1203: reforming context information based on primary information and the reduced secondary information.

FIG. 13 is a schematic diagram of a procedure for updating dynamic reduction of context information according to an embodiment of this application. As shown in FIG. 13, the procedure may include the following steps:
S1301: incrementing a current context counter;
S1302: determining whether N (i₁, i₂′)≥a threshold th;
S1303: updating secondary information; and
S1304: updating reformed context information.

It should be noted that, during update dynamic reduction (update dynamic reduction), for update of secondary information (update DRᵢ₁ⁿ into DRAᵢ₁ⁿ⁺¹), an updated context mainly inherits a coder index value to which an original context is mapped (LUT for coder (context index)).

It should be further noted that for step S1302, if a determining result is no, DRᵢ₁ⁿ is outputted; if the result is yes, steps S1303 and S1304 are performed, and DRᵢ₁ⁿ⁺¹ is finally outputted.

In other words, in embodiments of this application, after original context information bins (i₁, i₂) are divided into primary information i₁ and secondary information i₂ (as shown in FIG. 12), a reduction operation is performed only on the secondary information i₂, that is, a k bit of i₂ is set to 0 (truncation) to obtain the secondary information i′₂, and then context information is reformed to constitute a context status D(i₁,i′₂); each context status D has a counter N(i₁,i′₂) to record a quantity of times of accessing a current state D. A “dynamic reduction” process is embodied in procedure in FIG. 13. If N(i₁,i′₂) is greater than a preset threshold th, truncating k-bit secondary information is changed to truncating (k−1)-bit secondary information in the original context information bins, then the context information is reformed, and a new state D (i₁,i″₂) is activated, that is, a syntax element to be encode subsequently will use more secondary information to form a new context state, which means that the reduced secondary information is dynamically adjusted. In this way, coding processing is implemented for a current syntax element.

In this way, in embodiments of this application, based on a general test software TMC13 V20 of G-PCC, this technical solution is performed in a lossless condition, and bitstream performance comparison of octree geometry encoding is shown in Table 27. It may be learned from Table 27 that performance of geometry bitstreams obtained by the technical solution remains unchanged on these data.

TABLE 27
Performance results for the technical solution

| Sequence | bpip ratio [%] |
|---|---|
| basketball_player_vox11_00000200 | 100% |
| dancer_vox11_00000001 | 100% |
| facade_00064_vox11 | 100% |
| longdress_vox10_1300 | 100% |
| loot_vox10_1200 | 100% |
| queen_0200 | 100% |
| redandblack_vox10_1550 | 100% |
| soldier_vox10_0690 | 100% |
| thaidancer_viewdep_vox12 | 100% |
| Average (average) | 100% |

In embodiments of this application, specific implementations of the foregoing embodiments are described in detail by using the foregoing embodiments. It may be learned from the technical solutions of the foregoing embodiments, an actual meaning of context identifier information is considered, and validity of an encoded symbol in the context is also considered. Thus, accuracy of constructed context information can be improved to select an optimal target encoder for encoding. In this way, coding performance can be maintained, and coding efficiency can also be improved.

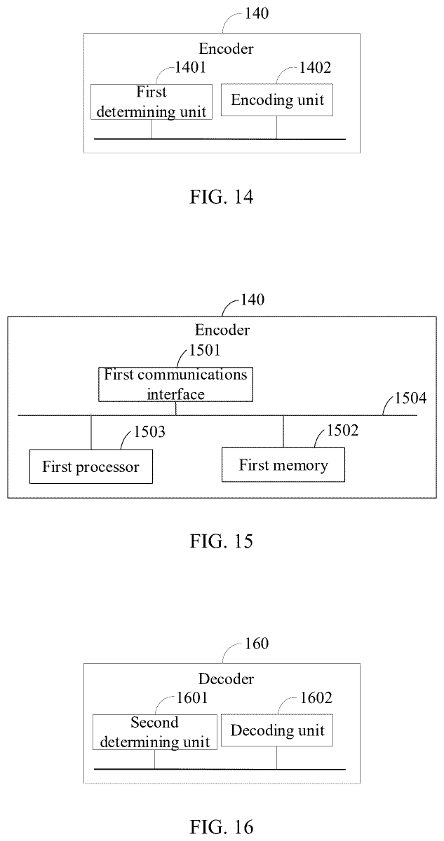

In still another embodiment of this application, based on a same invention concept of foregoing embodiments, FIG. 14 is a schematic diagram of a structure of an encoder according to an embodiment of this application. As shown in FIG. 14, the encoder 140 may include a first determining unit 1401 and an encoding unit 1402.

The first determining unit 1401 is configured to: determine occupancy information of reference child nodes of a current child node; determine preset identifier information of the current child node based on the occupancy information of the reference child nodes; and determine context information of the current child node based on the preset identifier information.

The encoding unit 1402 is configured to encode a value of a to-be-encoded syntax element of the current child node based on the context information, and write an obtained encoded bit into a bitstream.

In some embodiments, the reference child nodes may include at least one of the following:
an encoded sibling node of the current child node;
an encoded child node adjacent to the current child node in a first preset direction;
an encoded child node adjacent to the current child node in a second preset direction;
an encoded child node adjacent to the current child node in a third preset direction; or
an encoded child node adjacent to the current child node in a fourth preset direction.

In some embodiments, the first determining unit 1401 is further configured to: determine identifier information of a first target bit of the current child node based on the occupancy information of the reference child nodes when the current child node meets a first condition; or determine identifier information of a second target bit of the current child node based on the occupancy information of the reference child nodes when the current child node meets a second condition.

In some embodiments, the first determining unit 1401 is further configured to adjust an identifier policy of the second target bit to determine the identifier information of the second target bit of the current child node when the current child node meets the second condition.

In some embodiments, the first determining unit 1401 is further configured to determine that the current child node meets the first condition, including that the current child node is either a zeroth child node or a fourth child node; and further configured to determine that the current child node meets the second condition, including that the current child node is one of a first child node, a second child node, a third child node, a fifth child node, and a sixth child node. The zeroth child node, the first child node, the second child node, the third child node, the fourth child node, the fifth child node, and the sixth child node are sequentially child nodes to be encoded in sequence according to a preset scanning order in the current node.

In some embodiments, when the current child node is the zeroth child node, the first determining unit 1401 is further configured to: determine, based on occupancy information of an encoded child node adjacent to the zeroth child node in a first preset direction, identifier information of an m^{th} bit of the zeroth child node in a case of a first category; determine, based on occupancy information of an encoded child node adjacent to the zeroth child node in a second preset direction, identifier information of an (m−1)^{th} bit of the zeroth child node in the case of the first category; and determine, based on occupancy information of an encoded child node adjacent to the zeroth child node in a third preset direction, identifier information of an (m−2)^{th} bit of the zeroth child node in the case of the first category. Herein m is a highest bit number of the zeroth child node in the case of the first category.

In some embodiments of this application, the first preset direction is a left direction from the zeroth child node, the second preset direction is a front direction from the zeroth child node, and the third preset direction is a bottom direction from the zeroth child node.

In some embodiments, when the current child node is a fourth child node, the first determining unit 1401 is further configured to: determine identifier information of an nth bit of the fourth child node in a case of a first category based on occupancy information of encoded child nodes adjacent to the fourth child node in a fourth preset direction, a second preset direction, and a third preset direction; determine identifier information of an (n−1)^{th} bit of the fourth child node in the case of the first category based on occupancy information of an encoded child node adjacent to the fourth child node in the fourth preset direction; determine identifier information of an (n−2)^{th} bit of the fourth child node in the case of the first category based on occupancy information of an encoded child node adjacent to the fourth child node in the second preset direction; and determine identifier information of an (n−3)^{th} bit of the fourth child node in the case of the first category based on occupancy information of an encoded child node adjacent to the fourth child node in the third preset direction. Herein n is a highest bit number of the fourth child node in the case of the first category.

In some embodiments, the fourth preset direction is a left direction formed based on the zeroth child node, the first child node, the second child node, and the third child node, the second preset direction is a front direction from the fourth child node, and the third preset direction is a bottom direction from the fourth child node.

In some embodiments, when the current child node meets the second condition, the first determining unit 1401 is further configured to: determine identifier information of a k1^{th} bit of the first child node in a case of a first category based on occupancy information of an encoded child node adjacent to the first child node in a left direction; or determine identifier information of a k2^{th} bit of the second child node in a case of a first category based on occupancy information of an encoded child node adjacent to the second child node in a left direction; or determine identifier information of a k3^{th} bit of the third child node in a case of a second category based on occupancy information of the zeroth child node, the first child node, and the second child node; or determine identifier information of a k4^{th} bit of the fifth child node based on occupancy information of the zeroth child node, the first child node, the second child node, and the third child node; or determine identifier information of a k5^{th} bit of the sixth child node in a case of a first category based on occupancy information of the zeroth child node, the first child node, the second child node, and the third child node, where k1, k2, k3, k4, and k5 are all positive integers.

In some embodiments, the first determining unit 1401 is further configured to: set a value of each of k1, k2, k4, and k5 to 16; and set a value of k3 to 17.

In some embodiments, the first determining unit 1401 is further configured to: determine a number of occupied child nodes of the reference child nodes based on the occupancy information of the reference child nodes; and determine a local sparse category of the current child node based on the number of occupied child nodes of the reference child nodes.

In some embodiments, the first determining unit 1401 is further configured to: in a case that the number of occupied child nodes of the reference child nodes is greater than a first threshold, determine that the local sparse category of the current child node is a first category; and/or in a case that the number of occupied child nodes of the reference child nodes is less than or equal to a first threshold, determine that the local sparse category of the current child node is a second category.

In some embodiments, the first determining unit 1401 is further configured to perform correction processing on a third target bit processed by a negation operation in the context information, to determine identifier information of the third target bit in the context information.

In some embodiments, the first determining unit 1401 is further configured to adjust a position of the preset identifier information in the context information.

It may be understood that, in embodiments of this application, the term “unit” may be a partial circuit, a partial processor, a partial program or software, or the like. Certainly, the term “unit” may be a module or may be in a non-modular form. In addition, component parts in embodiments may be integrated into one processing unit, or each of the units may exist alone physically, or two or more units may be integrated into one unit. The foregoing integrated unit may be implemented in a form of hardware, or may be implemented in a form of a software functional module.

When the integrated unit is implemented in a form of a software functional module and not sold or used as an independent product, the integrated unit may be stored in a computer-readable storage medium. Based on such an understanding, the technical solutions of embodiments essentially, or the part contributing to the conventional technology, or all or a part of the technical solutions may be implemented in a form of a software product. The computer software product is stored in a storage medium and includes several instructions for instructing a computer device (which may be a personal computer, a server, or a network device) or a processor to execute all or a part of the steps of the methods described in the embodiments. The foregoing storage medium includes various media that may store a program code, such as a USB flash drive, a removable hard disk, a read-only memory (ROM), a random access memory (RAM), a magnetic disk, or an optical disk.

Therefore, an embodiment of this application provides a computer-readable storage medium, applied to the encoder 140. The computer-readable storage medium stores a computer program, and the computer program is executed by a first processor to implement the encoding method according to any one of the foregoing embodiments.

Based on the composition of the encoder 140 and the computer-readable storage medium, referring to FIG. 15, FIG. 15 is a schematic diagram of a structure of specific hardware of the encoder 140 according to an embodiment of this application. As shown in FIG. 15, the encoder 140 may include a first communications interface 1501, a first memory 1502, and a first processor 1503. The components are coupled together by using a first bus system 1504. It may be understood that the first bus system 1504 is configured to implement connection and communication between these components. The first bus system 1504 may further include a power bus, a control bus, a status signal bus, and the like in addition to a data bus. However, for clarity of description, various buses are marked as the first bus system 1504 in FIG. 15.

The first communications interface 1501 is configured to receive and transmit signals in the process of transmitting and receiving information with other external network elements.

The first memory 1502 is configured to store a computer program runnable on the first processor 1503.

The first processor 1503 is configured to run the computer program to perform the following operations:
determining occupancy information of reference child nodes of a current child node;
determining preset identifier information of the current child node based on the occupancy information of the reference child nodes;
determining context information of the current child node based on the preset identifier information; and
encoding a value of a to-be-encoded syntax element of the current child node based on the context information, and writing an encoded bit into a bitstream.

It may be understood that, in embodiments of this application, the first memory 1502 may be a volatile memory or a non-volatile memory, or may include both a volatile memory and a non-volatile memory. The non-volatile memory may be a read-only memory (Read-Only Memory, ROM), a programmable read-only memory (Programmable ROM, PROM), an erasable programmable read-only memory (Erasable PROM, EPROM), an electrically erasable programmable read-only memory (Electrically EPROM, EEPROM), or a flash memory. The volatile memory may be a random access memory (RAM), and is used as an external cache. By way of example rather than limitative description, many forms of RAMs are available, for example, a static random access memory (Static RAM, SRAM), a dynamic random access memory (Dynamic RAM, DRAM), a synchronous dynamic random access memory (Synchronous DRAM, SDRAM), a double data rate synchronous dynamic random access memory (Double Data Rate SDRAM, DDRSDRAM), an enhanced synchronous dynamic random access memory (Enhanced SDRAM, ESDRAM), a synchlink dynamic random access memory (Synchlink DRAM, SLDRAM), and a direct Rambus random access memory (Direct Rambus RAM, DRRAM). The first memory 1502 in the systems and the methods described in this application include but are not limited to these and any memory of another appropriate type.

However, the first processor 1503 may be an integrated circuit chip having a signal processing capability. In an implementation process, steps in the foregoing method can be implemented by using a hardware integrated logical circuit in the first processor 1503, or by using instructions in a form of software. The first processor 1503 may be a general-purpose processor, a digital signal processor (DSP), an application-specific integrated circuit (ASIC), a field programmable gate array (FPGA) or another programmable logic device, a discrete gate or a transistor logic device, or a discrete hardware component. The first processor 1503 may implement or execute the methods, steps, and logical block diagrams disclosed in embodiments of this application. The general-purpose processor may be a microprocessor, or the processor may be any conventional processor or the like. The steps of the methods disclosed with reference to embodiments of this application may be directly implemented by a hardware decoding processor, or may be implemented by a combination of hardware and software modules in a decoding processor. The software module may be located in a mature storage medium in the art, for example, a random access memory, a flash memory, a read-only memory, a programmable read-only memory, an erasable programmable memory, or a register. The storage medium is located in the first memory 1502, and the first processor 1503 reads information in the first memory 1502 and completes the steps of the foregoing methods in combination with hardware of the first processor.

It may be understood that these embodiments described in this application may be implemented by hardware, software, firmware, middleware, microcode, or a combination thereof. For hardware implementation, the processing unit may be implemented in one or more application-specific integrated circuits (ASIC), digital signal processors (DSP), digital signal processing devices (DSP Device, DSPD), programmable logic devices (PLD), field programmable gate arrays (FPGA), general-purpose processors, controllers, microcontrollers, microprocessors, and other electronic units configured to perform the functions described in this application, or a combination thereof. For software implementation, the techniques described in this application can be implemented by modules (such as processes and functions) that perform the functions described in this application. Software code may be stored in a memory and executed by a processor. The memory can be implemented in the processor or outside the processor.

Optionally, in another embodiment, the first processor 1503 is further configured to run the computer program to perform the encoding method according to any one of the foregoing embodiments.

An embodiment provides an encoder. In this encoder, an actual meaning can be assigned to the identifier information in the context information, and an encoded symbol bit can be made valid. Thus, accuracy of constructed context information can be improved to select an optimal target encoder for encoding. In this way, coding performance can be maintained, and coding efficiency can also be improved.

In still another embodiment of this application, based on a same invention concept of foregoing embodiments, FIG. 16 is a schematic diagram of a structure of a decoder according to an embodiment of this application. As shown in FIG. 16, the decoder 160 may include a second determining unit 1601 and a decoding unit 1602.

The second determining unit 1601 is configured to: determine occupancy information of reference child nodes of a current child node; determine preset identifier information of the current child node based on the occupancy information of the reference child nodes; and determine context information of the current child node based on the preset identifier information.

The decoding unit 1602 is configured to decode a to-be-decoded syntax element of the current child node based on the context information, to determine a value of the to-be-decoded syntax element.

In some embodiments, the reference child nodes may include at least one of the following:
a decoded sibling node of the current child node;
a decoded child node adjacent to the current child node in a first preset direction;
a decoded child node adjacent to the current child node in a second preset direction;
a decoded child node adjacent to the current child node in a third preset direction; or
a decoded child node adjacent to the current child node in a fourth preset direction.

In some embodiments, the second determining unit 1601 is further configured to: determine identifier information of a first target bit of the current child node based on the occupancy information of the reference child nodes when the current child node meets a first condition; or determine identifier information of a second target bit of the current child node based on the occupancy information of the reference child nodes when the current child node meets a second condition.

In some embodiments, the second determining unit 1601 is further configured to adjust an identifier policy of the second target bit to determine the identifier information of the second target bit of the current child node when the current child node meets the second condition.

In some embodiments, the second determining unit 1601 is further configured to determine that the current child node meets the first condition, including that the current child node is either a zeroth child node or a fourth child node; and further configured to determine that the current child node meets the second condition, including that the current child node is one of a first child node, a second child node, a third child node, a fifth child node, and a sixth child node. the zeroth child node, the first child node, the second child node, the third child node, the fourth child node, the fifth child node, and the sixth child node are sequentially child nodes to be decoded in sequence according to a preset scanning order in the current node.

In some embodiments, when the current child node is the zeroth child node, the second determining unit 1601 is further configured to: determine, based on occupancy information of a decoded child node adjacent to the zeroth child node in a first preset direction, identifier information of an m^{th} bit of the zeroth child node in a case of a first category; determine, based on occupancy information of a decoded child node adjacent to the zeroth child node in a second preset direction, identifier information of an (m−1)^{th} bit of the zeroth child node in the case of the first category; and determine, based on occupancy information of a decoded child node adjacent to the zeroth child node in a third preset direction, identifier information of the (m−2)^{th} bit of the zeroth child node in the case of the first category. Herein m is a highest bit number of the zeroth child node in the case of the first category.

In some embodiments of this application, the first preset direction is a left direction from the zeroth child node, the second preset direction is a front direction from the zeroth child node, and the third preset direction is a bottom direction from the zeroth child node.

In some embodiments, when the current child node is a fourth child node, the second determining unit 1601 is further configured to: determine identifier information of an nth bit of the fourth child node in a case of a first category based on occupancy information of decoded child nodes adjacent to the fourth child node in a fourth preset direction, a second preset direction, and a third preset direction; determine identifier information of an (n−1)^{th} bit of the fourth child node in the case of the first category based on occupancy information of a decoded child node adjacent to the fourth child node in the fourth preset direction; determine identifier information of an (n−2)^{th} bit of the fourth child node in the case of the first category based on occupancy information of a decoded child node adjacent to the fourth child node in the second preset direction; and determine identifier information of an (n−3)^{th} bit of the fourth child node in the case of the first category based on occupancy information of a decoded child node adjacent to the fourth child node in the third preset direction. Herein n is a highest bit number of the fourth child node in the case of the first category.

In some embodiments, the fourth preset direction is a left direction formed based on the zeroth child node, the first child node, the second child node, and the third child node, the second preset direction is a front direction from the fourth child node, and the third preset direction is a bottom direction from the fourth child node.

In some embodiments, when the current child node meets the second condition, the second determining unit 1601 is further configured to: determine identifier information of a k1^{th} bit of the first child node in a case of a first category based on occupancy information of a decoded child node adjacent to the first child node in a left direction; or determine identifier information of a k2^{th} bit of the second child node in a case of a first category based on occupancy information of a decoded child node adjacent to the second child node in a left direction; or determine identifier information of a k3^{th} bit of the third child node in a case of a second category based on occupancy information of the zeroth child node, the first child node, and the second child node; or determine identifier information of a k4^{th} bit of the fifth child node based on occupancy information of the zeroth child node, the first child node, the second child node, and the third child node; or determine identifier information of a k5^{th} bit of the sixth child node in a case of a first category based on occupancy information of the zeroth child node, the first child node, the second child node, and the third child node, where k1, k2, k3, k4, and k5 are all positive integers.

In some embodiments, the second determining unit 1601 is further configured to: set a value of each of k1, k2, k4, and k5 to 16; and set a value of k3 to 17.

In some embodiments, the second determining unit 1601 is further configured to: determine a number of occupied child nodes of the reference child nodes based on the occupancy information of the reference child nodes; and determine a local sparse category of the current child node based on the number of occupied child nodes of the reference child nodes.

In some embodiments, the second determining unit 1601 is further configured to: in a case that the number of occupied child nodes of the reference child nodes is greater than a first threshold, determine that the local sparse category of the current child node is a first category; and/or in a case that the number of occupied child nodes of the reference child nodes is less than or equal to a first threshold, determine that the local sparse category of the current child node is a second category.

In some embodiments, the second determining unit 1601 is further configured to perform correction processing on a third target bit processed by a negation operation in the context information, to determine identifier information of the third target bit in the context information.

In some embodiments, the second determining unit 1601 is further configured to adjust a position of the preset identifier information in the context information.

It may be understood that in embodiments, the term “unit” may be a partial circuit, a partial processor, a partial program or software, or the like. Certainly, the term “unit” may be a module or may be in a non-modular form. In addition, component parts in embodiments may be integrated into one processing unit, or each of the units may exist alone physically, or two or more units may be integrated into one unit. The foregoing integrated unit may be implemented in a form of hardware, or may be implemented in a form of a software functional module.

When the integrated unit is implemented in the form of a software functional module and not sold or used as an independent product, the integrated unit may be stored in a computer-readable storage medium. Based on such an understanding, an embodiment provides a computer-readable storage medium, applied to a decoder 160. The computer-readable storage medium stores a computer program, and the computer program is executed by a second processor to implement the decoding method according to any one of the foregoing embodiments.

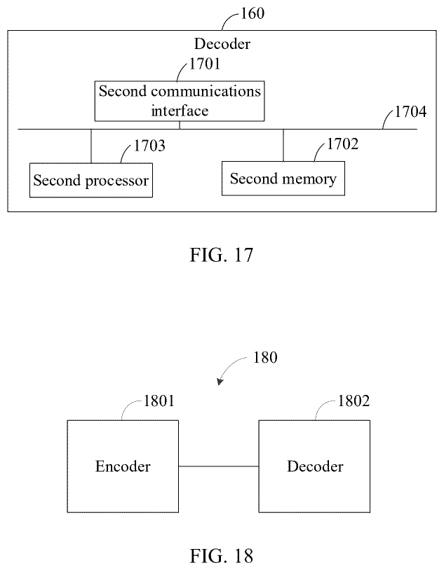

Based on the decoder 160 and the computer-readable storage medium, referring to FIG. 17, FIG. 17 is a schematic diagram of a hardware structure of the decoder 160 according to an embodiment of this application. As shown in FIG. 17, the decoder 170 may include a second communications interface 1701, a second memory 1702, and a second processor 1703. The components are coupled together by using a second bus system 1704. It may be understood that the second bus system 1704 is configured to implement connection and communication between these components. The second bus system 1704 may further include a power bus, a control bus, a status signal bus, and the like, in addition to a data bus. However, for clarity of description, various buses are marked as the second bus system 1704 in FIG. 17.

The second communications interface 1701 is configured to receive and transmit a signal in a process of transmitting and receiving information between the second communications interface and another external network element.

The second memory 1702 is configured to store a computer program runnable on the second processor 1703.

The second processor 1703 is configured to run the computer program to perform the following operations:
determining occupancy information of reference child nodes of a current child node;
determining preset identifier information of the current child node based on the occupancy information of the reference child nodes;
determining context information of the current child node based on the preset identifier information; and
decoding a to-be-decoded syntax element of the current child node based on the context information, to determine a value of the to-be-decoded syntax element.

Optionally, in another embodiment, the second processor 1703 is further configured to run the computer program to perform the decoding method according to any one of the foregoing embodiments.

It may be understood that hardware functions of the second memory 1702 are similar to those of the first memory 1502, and hardware functions of the second processor 1703 are similar to those of the first processor 1503. Details are not described herein again.

An embodiment provides a decoder. In this decoder, an actual meaning can be assigned to the identifier information in the context information, and an encoded symbol bit can be made valid. Thus, accuracy of constructed context information can be improved to select an optimal target encoder for encoding. In this way, coding performance can be maintained, and coding efficiency can also be improved.

FIG. 18 is a schematic structural diagram of a coding system according to still another embodiment of this application. As shown in FIG. 18, a coding system 180 may include an encoder 1801 and a decoder 1802.

In embodiments of this application, the encoder 1801 may be the encoder according to any one of foregoing embodiments, and the decoder 1802 may be the decoder according to any one of foregoing embodiments.

It should be noted that in this application, the terminology “include”, “comprise” or any other variant is intended to cover non-exclusive inclusion, so that a process, a method, an object or an apparatus that includes a series of elements not only includes those elements, but also includes other elements that are not explicitly listed, or includes inherent elements of the process, method, object or apparatus. In the absence of further restrictions, the element limited by the sentence “including a . . . ” does not exclude the existence of other identical elements in the process, method, item or device including this element.

The sequence numbers of the embodiments of this application are only for description, and do not represent superiority or inferiority of the embodiments.

The disclosed methods provided in the several method embodiments of this application may be randomly combined with each other in the case of no conflicts, to obtain new method embodiments.

The disclosed features provided in the several product embodiments of this application may be randomly combined with each other in the case of no conflicts, to obtain new product embodiments.

The disclosed features provided in the several method or device embodiments of this application may be randomly combined with each other in the case of no conflicts, to obtain new method embodiments or device embodiments.

The foregoing descriptions are merely specific implementations of this application, but the protection scope of this application is not limited thereto. Any variation or replacement readily figured out by a person skilled in the art within the technical scope disclosed in this application shall fall within the protection scope of this application. Therefore, the protection scope of this application shall be subject to the protection scope of the claims.

### INDUSTRIAL APPLICABILITY

In embodiments of this application, on both an encoding side and a decoding side, occupancy information of reference child nodes of a current child node is first determined; preset identifier information of the current child node is determined based on the occupancy information of the reference child nodes; and context information of the current child node is determined based on the preset identifier information. Finally, on the encoding side, a value of a to-be-encoded syntax element of the current child node is encoded based on the context information, and an encoded bit is written into a bitstream, so that on the decoding side, the to-be-decoded syntax element of the current child node is decoded based on the context information, and the value of the to-be-decoded syntax element can be determined. In this way, an actual meaning can be assigned to the identifier information in the context information, and an encoded symbol bit can be made valid. Thus, accuracy of constructed context information can be improved to select an optimal target encoder for encoding. In this way, coding performance can be maintained, and coding efficiency can also be improved.

1. A decoding method, applied to a decoder, wherein the method comprises:
determining occupancy information of reference child nodes of a current child node;
determining preset identifier information of the current child node based on the occupancy information of the reference child nodes;
determining context information of the current child node based on the preset identifier information; and
decoding a to-be-decoded syntax element of the current child node based on the context information, to determine a value of the to-be-decoded syntax element.

2. The method according to claim 1, wherein the determining the preset identifier information of the current child node based on the occupancy information of the reference child nodes comprises:
determining identifier information of a first target bit of the current child node based on the occupancy information of the reference child nodes when the current child node meets a first condition; or
determining identifier information of a second target bit of the current child node based on the occupancy information of the reference child nodes when the current child node meets a second condition.

3. The method according to claim 2, wherein when the current child node meets the second condition, the method further comprises:
adjusting an identifier policy of the second target bit to determine the identifier information of the second target bit of the current child node.

4. The method according to claim 2, wherein
the current child node meeting the first condition comprises that the current child node is either a zeroth child node or a fourth child node;
the current child node meeting the second condition comprises that the current child node is one of a first child node, a second child node, a third child node, a fifth child node, and a sixth child node; and
the zeroth child node, the first child node, the second child node, the third child node, the fourth child node, the fifth child node, and the sixth child node are sequentially child nodes to be decoded in sequence according to a preset scanning order in the current node.

5. The method according to claim 4, wherein when the current child node is the zeroth child node, the determining the identifier information of the first target bit of the current child node based on the occupancy information of the reference child nodes comprises:
determining, based on occupancy information of a decoded child node adjacent to the zeroth child node in a first preset direction, identifier information of an m^{th} bit of the zeroth child node in a case of a first category;
determining, based on occupancy information of a decoded child node adjacent to the zeroth child node in a second preset direction, identifier information of an (m−1)^{th} bit of the zeroth child node in the case of the first category; and
determining, based on occupancy information of a decoded child node adjacent to the zeroth child node in a third preset direction, identifier information of an (m−2)^{th} bit of the zeroth child node in the case of the first category,
wherein m is a highest bit number of the zeroth child node in the case of the first category.

6. The method according to claim 5, wherein
the first preset direction is a left direction from the zeroth child node, the second preset direction is a front direction from the zeroth child node, and the third preset direction is a bottom direction from the zeroth child node.

7. The method according to claim 4, wherein when the current child node is the fourth child node, the determining the identifier information of the first target bit of the current child node based on the occupancy information of the reference child nodes comprises:
determining identifier information of an nth bit of the fourth child node in a case of a first category based on occupancy information of decoded child nodes adjacent to the fourth child node in a fourth preset direction, a second preset direction, and a third preset direction;
determining identifier information of an (n−1)^{th} bit of the fourth child node in the case of the first category based on occupancy information of a decoded child node adjacent to the fourth child node in the fourth preset direction;
determining identifier information of an (n−2)^{th} bit of the fourth child node in the case of the first category based on occupancy information of a decoded child node adjacent to the fourth child node in the second preset direction; and
determining identifier information of an (n−3)^{th} bit of the fourth child node in the case of the first category based on occupancy information of a decoded child node adjacent to the fourth child node in the third preset direction,
wherein n is a highest bit number of the fourth child node in the case of the first category.

8. The method according to claim 7, wherein
the fourth preset direction is a left direction formed based on the zeroth child node, the first child node, the second child node, and the third child node, the second preset direction is a front direction from the fourth child node, and the third preset direction is a bottom direction from the fourth child node.

9. The method according to claim 4, wherein the determining the identifier information of the second target bit of the current child node based on the occupancy information of the reference child nodes when the current child node meets the second condition comprises:
determining identifier information of a k1^{th} bit of the first child node in a case of a first category based on occupancy information of a decoded child node adjacent to the first child node in a left direction; or
determining identifier information of a k2^{th} bit of the second child node in a case of a first category based on occupancy information of a decoded child node adjacent to the second child node in a left direction; or
determining identifier information of a k3^{th} bit of the third child node in a case of a second category based on occupancy information of the zeroth child node, the first child node, and the second child node; or
determining identifier information of a k4^{th} bit of the fifth child node based on occupancy information of the zeroth child node, the first child node, the second child node, and the third child node; or
determining identifier information of a k5^{th} bit of the sixth child node in a case of a first category based on occupancy information of the zeroth child node, the first child node, the second child node, and the third child node, wherein k1, k2, k3, k4, and k5 are all positive integers.

10. The method according to claim 1, wherein the method further comprises:
determining a number of occupied child nodes of the reference child nodes based on the occupancy information of the reference child nodes; and
determining a local sparse category of the current child node based on the number of occupied child nodes of the reference child nodes;
wherein the determining the local sparse category of the current child node based on the number of occupied child nodes of the reference child nodes comprises:
in a case that the number of occupied child nodes of the reference child nodes is greater than a first threshold, determining that the local sparse category of the current child node is a first category;
in a case that the number of occupied child nodes of the reference child nodes is less than or equal to a first threshold, determining that the local sparse category of the current child node is a second category.

11. The method according to claim 1, wherein the method further comprises:
performing correction processing on a third target bit processed by a negation operation in the context information, to determine identifier information of the third target bit in the context information.

12. The method according to claim 1, wherein the method further comprises:
adjusting a position of the preset identifier information in the context information.

13. An encoding method, applied to an encoder, wherein the method comprises:
determining occupancy information of reference child nodes of a current child node;
determining preset identifier information of the current child node based on the occupancy information of the reference child nodes;
determining context information of the current child node based on the preset identifier information; and
encoding a value of a to-be-encoded syntax element of the current child node based on the context information, and writing an encoded bit into a bitstream.

14. The method according to claim 13, wherein the determining the preset identifier information of the current child node based on the occupancy information of the reference child nodes comprises:
determining identifier information of a first target bit of the current child node based on the occupancy information of the reference child nodes when the current child node meets a first condition; or
determining identifier information of a second target bit of the current child node based on the occupancy information of the reference child nodes when the current child node meets a second condition.

15. The method according to claim 14, wherein
the current child node meeting the first condition comprises that the current child node is either a zeroth child node or a fourth child node;
the current child node meeting the second condition comprises that the current child node is one of a first child node, a second child node, a third child node, a fifth child node, and a sixth child node; and
the zeroth child node, the first child node, the second child node, the third child node, the fourth child node, the fifth child node, and the sixth child node are sequentially child nodes to be encoded in sequence according to a preset scanning order in the current node.

16. The method according to claim 15, wherein when the current child node is the zeroth child node, the determining the identifier information of the first target bit of the current child node based on the occupancy information of the reference child nodes comprises:
determining, based on occupancy information of an encoded child node adjacent to the zeroth child node in a first preset direction, identifier information of an m^{th} bit of the zeroth child node in a case of a first category;
determining, based on occupancy information of an encoded child node adjacent to the zeroth child node in a second preset direction, identifier information of an (m−1)^{th} bit of the zeroth child node in the case of the first category; and
determining, based on occupancy information of an encoded child node adjacent to the zeroth child node in a third preset direction, identifier information of an (m−2)^{th} bit of the zeroth child node in the case of the first category,
wherein m is a highest bit number of the zeroth child node in the case of the first category.

17. The method according to claim 15, wherein when the current child node is the fourth child node, the determining the identifier information of the first target bit of the current child node based on the occupancy information of the reference child nodes comprises:
determining identifier information of an nth bit of the fourth child node in a case of a first category based on occupancy information of encoded child nodes adjacent to the fourth child node in a fourth preset direction, a second preset direction, and a third preset direction;
determining identifier information of an (n−1)^{th} bit of the fourth child node in the case of the first category based on occupancy information of an encoded child node adjacent to the fourth child node in the fourth preset direction;
determining identifier information of an (n−2)^{th} bit of the fourth child node in the case of the first category based on occupancy information of an encoded child node adjacent to the fourth child node in the second preset direction; and
determining identifier information of an (n−3)^{th} bit of the fourth child node in the case of the first category based on occupancy information of an encoded child node adjacent to the fourth child node in the third preset direction,
wherein n is a highest bit number of the fourth child node in the case of the first category.

18. The method according to claim 15, wherein the determining the identifier information of the second target bit of the current child node based on the occupancy information of the reference child nodes when the current child node meets the second condition comprises:
determining identifier information of a k1^{th} bit of the first child node in a case of a first category based on occupancy information of an encoded child node adjacent to the first child node in a left direction; or
determining identifier information of a k2^{th} bit of the second child node in a case of a first category based on occupancy information of an encoded child node adjacent to the second child node in a left direction; or
determining identifier information of a k3^{th} bit of the third child node in a case of a second category based on occupancy information of the zeroth child node, the first child node, and the second child node; or
determining identifier information of a k4^{th} bit of the fifth child node based on occupancy information of the zeroth child node, the first child node, the second child node, and the third child node; or
determining identifier information of a k5^{th} bit of the sixth child node in a case of a first category based on occupancy information of the zeroth child node, the first child node, the second child node, and the third child node, wherein k1, k2, k3, k4, and k5 are all positive integers.

19. The method according to claim 13, wherein the method further comprises:
performing correction processing on a third target bit processed by a negation operation in
the context information, to determine identifier information of the third target bit in the context information.

20. A non-transitory storage medium, storing a bitstream generated by:
determining occupancy information of reference child nodes of a current child node;
determining preset identifier information of the current child node based on the occupancy information of the reference child nodes;
determining context information of the current child node based on the preset identifier information; and
encoding a value of a to-be-encoded syntax element of the current child node based on the context information, and writing an encoded bit into the bitstream.
